(19) United States
(12) Patent Application Publication
(10) Pub. No.: US 2023/0279537 A1
(43) Pub. Date: Sep. 7, 2023

(54) COATING INSTALLATION, CLAMPING RING AND MAGAZINE FOR SPECTACLE LENSES AND METHOD OF COATING SPECTACLE LENSES

(71) Applicant: Schneider GmbH & Co. KG, Fronhausen (DE)

(72) Inventors: Gunter SCHNEIDER, Marburg (DE); Markus FUHR, Erlensee (DE); Klaus HOFMANN, Wehrheim (DE)

(21) Appl. No.: 17/926,310

(22) PCT Filed: May 17, 2021
(86) PCT No.: PCT/EP2021/062930

§ 371 Date: Nov. 18, 2022

(30) Foreign Application Priority Data
May 20, 2020 (DE) 10 2020 003 037.8
Jun. 15, 2020 (DE) 10 2020 003 578.7

(51) Int. Cl. C23C 14/50; C23C 14/56; C23C 14/54; C23C 14/24; C23C 14/34; B29D 11/00

(52) U.S. Cl. CPC C23C 14/505; B29D 11/00865; C23C 14/24; C23C 14/34; C23C 14/541; C23C 14/566; C23C 14/568

(57) ABSTRACT

A coating installation for coating a spectacle lens is proposed. Preferably, the coating installation comprises a handling system for the automated handling of clamping rings for temporarily holding the spectacle lens during the application of the coating. In particular, the handling system is designed for automated transfer of spectacle lenses between different apparatuses of the coating installation. Furthermore, a clamping ring for clamping a spectacle lens at the edge, a magazine for storing clamping rings, a processing installation for processing spectacle lenses and several methods for processing and/or coating spectacle lenses are proposed.

### CROSS-REFERENCE TO RELATED APPLICATIONS

This application is a national stage application under 35 U.S.C. 371 of PCT Application No. PCT/EP2021/062930, having an international filing date of 17 May 2021, which designated the United States, which PCT application claimed the benefit of German Patent Application No. 10 2020 003 037.8, filed 20 May 2020 and German Patent Application No. 10 2020 003 578.7, filed 15 Jun. 2020, each of which are incorporated herein by reference in their entirety.

### BACKGROUND

The present invention relates to a coating installation for coating a spectacle lens a clamping ring for edge clamping a spectacle lens, a magazine for storing clamping rings, and a method for coating spectacle lenses.

An installation for processing optical lenses is known from WO 2013/131656 A2. The system has several separate processing devices for independent processing of the lenses as well as a transfer system with parallel transport tracks for conveying the lenses. The coating of lenses is not discussed in detail.

WO 2018/153787 A1 also discloses a system for processing optical lenses. The installation comprises a blocking apparatus for blocking lenses to be processed, a plurality of processing apparatuses for processing the lenses, a deblocking apparatus for deblocking the processed lenses and a transport system for the lenses. The installation has a processing line for coating the lenses, wherein the processes in this processing line are not shown in detail.

An installation for coating spectacle lenses is known from DE 10 2016 125 273 A1 or WO 2018/108426 A1. The system has a transfer chamber and a plurality of coating apparatuses connected in parallel to the transfer chambers and having separate coating chambers for coating the spectacle lenses in a vacuum. The coating chambers and the transfer chamber form an interconnected vacuum system. An interaction between the coating installation and potentially upstream devices for mechanical processing of the spectacle lenses is not discussed.

DE 694 15 324 T2 or EP 0 714 454 B1 discloses a disc for holding spectacle lenses during a coating process. The disc can receive a lens holder in each of the outer indentations. The lenses held in the lens holders are moved past a sputtering device by rotating the disc so that the lenses are coated.

DE 101 46 542 A1 discloses a holder with flexible spring elements as holding means for lenses or spectacle lenses. The holder has indexing means formed by holes in radially outwardly pointing arms of the holder.

DE 692 00 590 T2 or EP 0 497 651 B1 discloses a holder for spectacle lenses, in which the spectacle lenses are held by elastically deformable tabs. The holder has a projection which forms a stop to define the position of individual holders on a common mount.

DE 10 2014 119 365 A1 relates to a substrate holding apparatus for various types of substrates. The substrate holding apparatus has spring-loaded holding structures by which a substrate resting on a supporting surface of the substrate holding apparatus can be held.

From the prior art, no installation is known in which spectacle lenses are first mechanically processed in a processing installation, in particular in parallel in several separate processing devices, and then automatically transferred to a coating installation and there automatically handled and/or provided with a coating, in particular in small groups.

Furthermore, the coating of spectacle lenses in methods known from the prior art is carried out in such a way that a large number of spectacle lenses are simultaneously fed to a coating device and coated there in so-called batch operation. A batch, i.e. a group of spectacle lenses which are coated simultaneously, typically comprises about 80 to 120 spectacle lenses. A disadvantage of this method is that it is necessary to wait until a sufficient number of lenses have accumulated before coating. As a result, the time required to produce a single lens or a pair of lenses for a pair of spectacles is relatively long, which ultimately results in a long waiting time for the customer who orders a new pair of spectacles or new lenses.

### SUMMARY

It is an object of the present invention to provide a solution for optimally connecting a coating installation for coating spectacle lenses to a processing installation for mechanically processing spectacle lenses, and to enable fully automated handling of spectacle lenses, in particular for and/or during the application of a permanent coating and/or to enable the shortest possible processing time for a spectacle lens in a processing installation and/or coating installation.

The above object is solved by a coating installation, a clamping ring, a magazine or a method as disclosed herein.

According to a first aspect, the present invention relates to a coating installation with a coating apparatus for applying a permanent coating to a spectacle lens.

The coating installation preferably has a handling system for the automated handling of holders, in particular clamping rings. The holders/clamping rings are designed to temporarily hold the spectacle lens during the application of the coating. The handling system enables fully automated handling of the holders/clamping rings and rapid passage of spectacle lenses through the coating installation.

Preferably, the coating installation comprises a first coating apparatus and a second coating apparatus. The coating apparatuses are preferably configured for applying different layers of the permanent coating to the spectacle lens. In particular, the first coating apparatus is configured to apply a first layer or hard layer and/or the second coating apparatus is configured to apply one or more second layers or functional layers.

Further, the coating installation preferably comprises an intermediate storage apparatus for intermediate storage of spectacle lenses after application of the first layer or hard layer and/or before application of the second layer or functional layer. The intermediate storage apparatus is preferably arranged downstream of the first coating apparatus and/or upstream of the second coating apparatus.

Preferably, the coating installation comprises a handling system for automated transfer of spectacle lenses between the first and/or second coating apparatus and the intermediate storage apparatus. This enables a fully automated process and a fast passage of spectacle lenses through the coating installation.

Particularly preferably, the handling system is designed both for the automated handling of holders/clamping rings and for the automated transfer of spectacle lenses. This enables a fully automated process.

Preferably, the handling system comprises a handling device with one or more suction cups or grippers for holding and/or handling a holder/clamping ring. Preferably, the handling device comprises or is formed by a robot, in particular with one or more robot arms.

Preferably, the handling device - in addition to handling holders/clamping rings - is designed for handling spectacle lenses. This is conducive to a compact design.

The coating installation and/or intermediate storage apparatus preferably has a magazine for storing clamping rings for the spectacle lenses. This is conducive to an efficient process.

The magazine preferably has a magazine unit which can be removed from the magazine together with the clamping rings arranged therein. In this way, a large number of clamping rings can be fed simultaneously to a cleaning device and cleaned there, and a process for cleaning the clamping rings can be designed to be particularly efficient and/or time-saving.

The coating installation and/or intermediate storage apparatus preferably comprises a device for automated opening and/or closing of a clamping ring. Alternatively or additionally, the device is designed for automated insertion of a spectacle lens in a clamping ring. This is conducive to a fully automated and efficient process.

The coating installation and/or intermediate storage apparatus further preferably comprises a heating device for heating spectacle lenses. In particular, heating in the heating device dries and/or cures a hard coating previously applied to the spectacle lenses, in particular in the first coating apparatus. Preferably, the spectacle lenses are held in clamping rings during heating in the heating device.

The coating installation and/or intermediate storage apparatus or heating device preferably comprises a transport device for transporting spectacle lenses through the intermediate storage apparatus and/or heating device. During transport, the spectacle lenses are preferably held in clamping rings. The heating device is designed to heat the spectacle lenses during transport of the spectacle lenses with the transport device. In other words, the lenses are heated while they are transported through the heating device.

Preferably, the heating device is designed for continuous transport of spectacle lenses, i.e. spectacle lenses are or can be transported in the heating device and/or with the transport device without interruptions. In particular, while one or more spectacle lenses are already being transported with the transport device, further spectacle lenses can be transferred to the transport device so that they are transported with the transport device.

In particular, the transport device has a continuously running conveyor belt, conveyor element or the like for this purpose. In this way, the processing time for a single spectacle lens through the coating installation can be shortened or optimised.

The coating installation and/or the handling system preferably has a (further) handling device for transferring spectacle lenses and/or clamping rings with spectacle lenses held therein from the intermediate storage apparatus and/or heating device, in particular the transport device of the heating device, to the second coating apparatus. In particular, this enables an automated transfer of spectacle lenses from the intermediate storage apparatus to the second coating apparatus. This is conducive to an optimized process.

The coating installation, in particular the second coating apparatus, preferably has at least one carrier for receiving a plurality of spectacle lenses held in holders/clamping rings. This allows several spectacle lenses to be coated simultaneously in the second coating apparatus.

Preferably, the carrier is designed as a cover for a coating chamber of the second coating apparatus. Optionally, the carrier is designed to close a coating chamber of the second coating apparatus during a coating process, in particular in a gas-tight or vacuum-tight manner. This is conducive to a simple construction of the coating apparatus and/or of the coating chamber, and to an optimized process and/or rapid passage of spectacle lenses through the coating apparatus.

The coating installation and/or second coating apparatus is preferably configured for automated return transport of the carrier after passing through the second coating apparatus. This is conducive to an automated and efficient process.

According to a further aspect, which can also be implemented independently, the present invention relates to a clamping ring having a plurality of flexible, in particular elastic, arms for clamping a spectacle lens at the edge.

According to a first aspect, the clamping ring comprises an orientation means for oriented gripping or handling of the clamping ring and/or for oriented insertion of the clamping ring into a magazine and/or a carrier. This enables automated handling of the clamping ring.

According to a further aspect, which may also be implemented independently, the clamping ring comprises a suction surface for handling the clamping ring by means of a suction cup. This enables easy handling of the clamping ring.

According to a further aspect, which can also be implemented independently, the clamping ring is designed in such a way that a plurality of identical clamping rings can be stacked vertically in such a way that the arms of adjacent clamping rings are spaced apart from one another and/or that arms of adjacent clamping rings do not touch one another. In particular, this enables space-saving storage of the clamping rings and/or storage that is optimized for automated handling and/or prevents arms of adjacent clamping rings from getting caught during stacking.

The orientation means is preferably arranged on an outer side of the clamping ring. Alternatively or additionally, the orientation means has or is formed by one or more recesses.

The suction surface is preferably formed by a flange and/or is ring-shaped. This gives the clamping ring a simple structure.

Preferably, the suction surface is at least substantially parallel to a plane in which the spectacle lens is clamped or can be clamped. This is conducive to a simple and compact design of the clamping ring.

The clamping ring preferably has a frame in which the arms are fixed, the frame projecting over the arms radially inwards and perpendicularly to a plane in which the spectacle lens is clamped or can be clamped. In particular, this can prevent the arms of adjacent clamping rings from contacting or interlocking with each other when the clamping rings are stacked.

The clamping ring or frame preferably has at least one recess. The recess is preferably arranged on a bottom side of the clamping ring and/or frame. Through the recesses, a drainage of cleaning liquid is made possible when several clamping rings, in particular clamping rings stacked on top of each other and/or arranged in a magazine or magazine unit, are cleaned simultaneously. This thus enables simultaneous cleaning of a plurality of clamping rings, which are arranged in particular in a magazine, and residues of cleaning liquid on the clamping rings are avoided.

According to another aspect which can also be implemented independently, the present invention relates to a magazine for storing a plurality of clamping rings for spectacle lenses.

Preferably, the clamping rings have an orientation means and the magazine also has an orientation means corresponding to the orientation means of the clamping rings, so that the clamping rings can only be arranged or stored in the magazine in a predetermined orientation or rotational position. This enables automated handling of the clamping rings.

The magazine preferably has at least one magazine unit which can be removed from the magazine together with clamping rings arranged in the magazine unit. This makes it possible to remove several clamping rings from the magazine at the same time and to clean them, for example. This is conducive to an efficient and fast process.

Preferably, several clamping rings can be stored stacked on top of each other in the magazine and/or magazine unit in the same orientation or rotational position. This is conducive to a compact design and enables automated handling of the clamping rings.

The magazine and/or magazine unit is preferably columnar in design. This is conducive to a simple design

According to another aspect which can also be implemented independently, the present invention relates to a processing installation for processing spectacle lenses.

The processing installation has several separate and independently operating processing apparatuses.

Preferably, at least one of the processing apparatuses is designed for machining/shaping processing and/or at least one of the processing apparatuses is designed for polishing spectacle lenses. Preferably, the apparatus is designed for simultaneously processing spectacle lenses in different processing apparatuses. In particular, spectacle lenses can thus be shaping processed/machined, for example milled or turned, in one or more machining apparatuses for shaping processing/ machining, while one or more spectacle lenses are also shaping processed/machined and/or polished in one or more other processing devices.

Preferably, the processing installation has a plurality of transport tracks so that spectacle lenses can be conveyed past processing apparatuses and/or can be circulated.

The processing installation preferably has a coating installation directly adjoining the processing apparatuses and connected to one of the transport tracks.

Furthermore, the processing installation preferably comprises a transfer device designed for automated transfer of the spectacle lenses from the transport track or one of the processing apparatuses to the coating installation.

The coating installation preferably comprises a plurality of coating chambers for applying different layers to the spectacle lenses. The or some coating chambers preferably form a contiguous vacuum system and are in particular arranged serially and/or directly connected to each other, so that the spectacle lenses pass through each of the coating chambers. However, in addition to the coating chambers forming a contiguous vacuum system, the coating installation may also comprise at least one further, separate coating chamber. The coating chambers forming the contiguous vacuum system are in particular the previously mentioned coating chambers of the second coating apparatus and/or designed for applying the second layer or functional layer(s). The coating chamber separate therefrom is preferably the aforementioned coating chamber of the first coating apparatus and/or designed for the application of the first layer or hard layer.

In particular, the processing installation combines a parallel processing of spectacle lenses in the processing apparatuses with a serial throughput of spectacle lenses in a coating installation. In particular, a short processing time and/or a fast throughput of a single spectacle lens through the entire processing installation can be realized in this way.

According to a further aspect which can also be implemented independently, the present invention relates to a method for applying a permanent coating to spectacle lenses in a coating installation. During the application of the permanent coating, the spectacle lenses are temporarily held in holders, in particular clamping rings. In this context, temporary means in particular that the spectacle lenses are preferably held in holders/clamping rings only during one or more steps of the application of the coating, and preferably at least one step in the application of the permanent coating takes place without the spectacle lenses being held in holders/clamping rings.

In this method, it is preferably provided that the coating installation automatically opens and/or closes the clamping rings and/or automatically inserts spectacle lenses into the clamping rings and/or removes them from the clamping rings. This is conducive to a rapid passage of spectacle lenses through the coating installation.

Alternatively or additionally, in this method it is preferably provided that the spectacle lenses or clamping rings are automatically inserted indirectly or directly into carriers which, in particular, rotatably hold the spectacle lenses or clamping rings during coating and/or cover individual coating chambers during coating, and/or are automatically removed from the carriers.

For opening and/or closing and/or inserting and/or removing a spectacle lens, the clamping rings are preferably held in a defined orientation or rotational position. This enables an automated process.

According to a further aspect, which can also be implemented independently, the present invention relates to a method for applying a permanent coating to a first and a second flat side of a spectacle lens. In this method, a removable cover layer is applied to the first flat side of the spectacle lens in a cover layer apparatus, and thereafter a permanent coating is applied to the second flat side.

After the permanent coating is applied to the second flat side, the removable cover layer is automatically removed from the spectacle lens and the spectacle lens is automatically transported back to the cover layer device.

Subsequently, a removable cover layer is applied to the second flat side in the cover layer device and then a permanent coating is applied to the first flat side.

By applying a removable cover layer to the side not intended for coating, it is prevented that a part of the coating material also reaches the side not intended for coating. This is conducive to optimum quality of the coating.

According to a further aspect which can also be implemented independently, the present invention relates to a method for processing a spectacle lens, wherein the spectacle lens is subjected to shaping processing/machining and preferably polishing in one or more processing apparatuses. Furthermore, a first flat side of the spectacle lens is provided with a removable protective layer prior to the shaping processing/machining. Preferably, the spectacle lens is blocked on the first flat side for or before the shaping processing/machining.

After shaping processing/machining, the protective layer is removed and, after the protective layer has been removed, the first flat side of the spectacle lens is provided with a removable cover layer.

A permanent coating is then applied to the second flat side of the lens.

Removing the protective layer after shaping processing/machining and applying the cover layer before coating ensures that the lens or the first flat side of the lens is completely covered during coating and that no coating material can get onto the first flat side.

According to another aspect which can also be implemented independently, the present invention relates to a method for applying a permanent coating to spectacle lenses in a coating installation, wherein the spectacle lenses are coated in batch sizes of at most eight spectacle lenses at a time.

Furthermore, the spectacle lenses are transported to the coating installation in transport containers and removed from the transport containers for coating and transferred to the coating installation.

During the application of the coating to the spectacle lenses, the transport containers are transported past the coating installation. After the coating has been applied, the spectacle lenses are each placed back in the same transport container from which they were previously removed.

Individual ones of the foregoing and subsequent aspects and features of the present invention may be combined with each other in various combinations, but may also be implemented independently of each other.

Further aspects, features, advantages and characteristics of the present invention will be apparent from the claims and the following description of preferred embodiments with reference to the drawing.

### BRIEF DESCRIPTION OF THE DRAWINGS

It shows:

FIG. 1 a schematic view of a processing installation according to the proposal for processing spectacle lenses;

FIG. 2 a schematic view of a blocked spectacle lens;

FIG. 3 a schematic view of a spectacle lens with a permanent coating;

FIG. 4 a schematic perspective view of a cleaning apparatus and a first coating apparatus;

FIG. 5 a schematic side view of the cleaning apparatus of FIG. 4;

FIG. 6 a schematic perspective view of the first coating apparatus of FIG. 4;

FIG. 7 a schematic perspective view of an intermediate storage apparatus;

FIG. 8 a schematic perspective view of a clamping ring;

FIG. 9 a schematic bottom view of the clamping ring of FIG. 8;

FIG. 10 a schematic perspective view of a magazine or magazine unit with a clamping ring arranged therein;

FIG. 11 a strip of a transport device of the intermediate storage apparatus;

FIG. 12 a top view of a clamping device for clamping a spectacle lens in a clamping ring;

FIG. 13 an enlarged section of FIG. 7;

FIG. 14 a schematic perspective view of a second coating apparatus;

FIG. 15 a schematic perspective view of a handling device of the second coating apparatus; and

FIG. 16 a schematic perspective view of a further handling device of the second coating apparatus.

### DETAILED DESCRIPTION

In the figures, some of which are not to scale and are only schematic, the same reference signs are used for the same or similar parts, wherein corresponding or comparable properties and advantages can be achieved, even if a repeated description is omitted.

Processing apparatuses “of the same kind” in the sense of the present invention are preferably processing apparatuses designed for the same type of processing and/or for performing the same processing step in the manufacture of spectacle lenses. Possible processing steps or “types” of processing include, for example, turning processing (abbreviated also as “turning”), milling machining (abbreviated as “milling”), marking, polishing, blocking and deblocking, said processing operations each representing different processing steps or types of processing. For example, two processing apparatuses each adapted for polishing spectacle lenses are processing apparatuses of the same kind. Particularly preferably, processing apparatuses of the same kind are of the same or identical design. Two processing apparatuses which are designed for different processing or processing steps are not of the same kind. For example, a processing apparatus for polishing and a processing apparatus for marking are not processing apparatuses of the same kind.

A “prescription surface” in the sense of the present invention is a surface or flat side of a spectacle lens whose geometric shape is to be altered by shaping processing/machining so that the shaping processing/machining of the prescription surface results in a spectacle lens that corrects a visual defect of a user for whom the spectacle lens is manufactured.

A “permanent” coating in the sense of the present invention is preferably a coating that cannot be removed again from the spectacle lens. In particular, a permanent coating serves to modify, in particular to improve or optimize, the properties of the spectacle lens, for example with respect to its reflective properties or with respect to the adhesion of dirt to the spectacle lens. Preferably, the coating comprises or consists of several different layers, in particular a hard layer and one or more functional layers. The hard layer serves in particular to protect the spectacle lens from being scratched. The functional layer serves in particular to enhance the spectacle lens or to increase the comfort for the user. In particular, a property of the spectacle lens or its surface may be modified by one or more functional layers. For example, a functional layer can reduce or prevent dirt, water, grease and/or dust particles from adhering to the spectacle lens, facilitate cleaning of the spectacle lens, reduce or prevent the occurrence of reflections (anti-reflection coating), and/or reduce the transmittance of the spectacle lens for light of a certain wavelength or colour, for example blue, violet and/or UV light.

A “protective layer” in the sense of the present invention is preferably a removable layer. In particular, the protective layer is a layer which serves to protect the spectacle lens during a processing operation and/or which is detached or removed after the processing operation. In particular, the protective layer is applied to the block side and/or the protective layer serves to prevent damage to the block side of the spectacle lens.

A “cover layer” in the sense of the present invention is preferably a removable layer. In particular, the cover layer is a layer which serves to cover a flat side of the spectacle lens during a coating operation and/or which is detached or removed again after the coating operation. In particular, the cover layer serves to prevent a deposit of coating material on the side of the spectacle lens not intended for coating.

The cover layer is preferably identical to the protective layer. The different terms cover layer and protective layer are primarily used to distinguish the layer applied to protect one side of the lens from damage during processing from the layer applied to cover the side not intended to be coated during application of the permanent coating.

A “block side” in the sense of the present invention is preferably a flat side of a spectacle lens at which the spectacle lens is held during a processing of the other flat side of the spectacle lens, in particular by means of a block piece and/or blocking material.

A “circulation” of spectacle lenses in the sense of the present invention is in particular a conveying or transport of spectacle lenses in a circuit, wherein a spectacle lens passes through at least one point of the circuit at least twice. In a circulation, a spectacle lens is preferably transported past one or more processing apparatuses without being fed to this processing apparatus or these processing apparatuses for processing.

A “parallel” processing of spectacle lenses in the sense of the present invention is in particular a processing in which a simultaneous processing of spectacle lenses takes place in similar, in particular separate, processing apparatuses. A processing installation designed for parallel processing of spectacle lenses therefore preferably has a plurality of processing apparatuses, preferably of the same kind, for carrying out a processing operation or a particular processing step, such as milling, polishing or the like. In particular, in the case of parallel processing, a specific type of processing or a specific processing step can optionally be carried out in one of a plurality of processing apparatuses, preferably of the same kind or type, so that it is not predetermined in which of the plurality of processing apparatuses the type of processing or the processing step is carried out.

A “serial” processing of spectacle lenses in the sense of the present invention is, in particular, a processing in which a certain type of processing or a certain processing step takes place in only one (single) processing apparatus. In particular, in contrast to parallel processing, no simultaneous processing of spectacle lenses takes place in similar processing apparatuses. A processing installation designed for serial processing of spectacle lenses therefore preferably has exactly one processing apparatus for each type of processing or for each processing step. Nevertheless, even in the case of serial processing or a processing installation designed for this purpose, the individual processing apparatuses can each be designed to process several spectacle lenses, even simultaneously. In contrast to parallel processing, however, it is intended that each spectacle lens passes through each processing apparatus at least once and/or is processed in each of the processing apparatuses.

A “holder” or “clamping ring” in the sense of the present invention is preferably a holder for holding a spectacle lens, in particular at the edge. In particular, a clamping ring is designed in such a way that at least one flat side of the spectacle lens remains free and/or can be coated with a coating. A clamping ring is preferably at least substantially ring-like in design and/or preferably has devices for holding a spectacle lens, in particular by frictional engagement and/or clamping, for example in the form of (flexible) arms, fingers, pins or the like.

A “magazine” in the sense of the present invention is preferably a device for storing and/or keeping clamping rings. Preferably, several clamping rings can be stored simultaneously in a magazine.

A “stacking” of clamping rings in the sense of the present invention is preferably an arrangement of two or more clamping rings in such a way that the clamping rings contact each other or rest against or on each other. Preferably, stacking involves arranging a plurality of clamping rings one on top of the other in the same orientation, in particular in a vertical direction.

A “gripper” in the sense of the present invention is preferably a holder for holding a spectacle lens, by means of which the spectacle lens can be held at the edge thereof, in particular so that damage to the surface of the spectacle lens or the flat sides of the spectacle lens is avoided. In particular, a gripper has a plurality of fingers which are or can be applied to the edge of the spectacle lens for holding it.

### Overall Concept

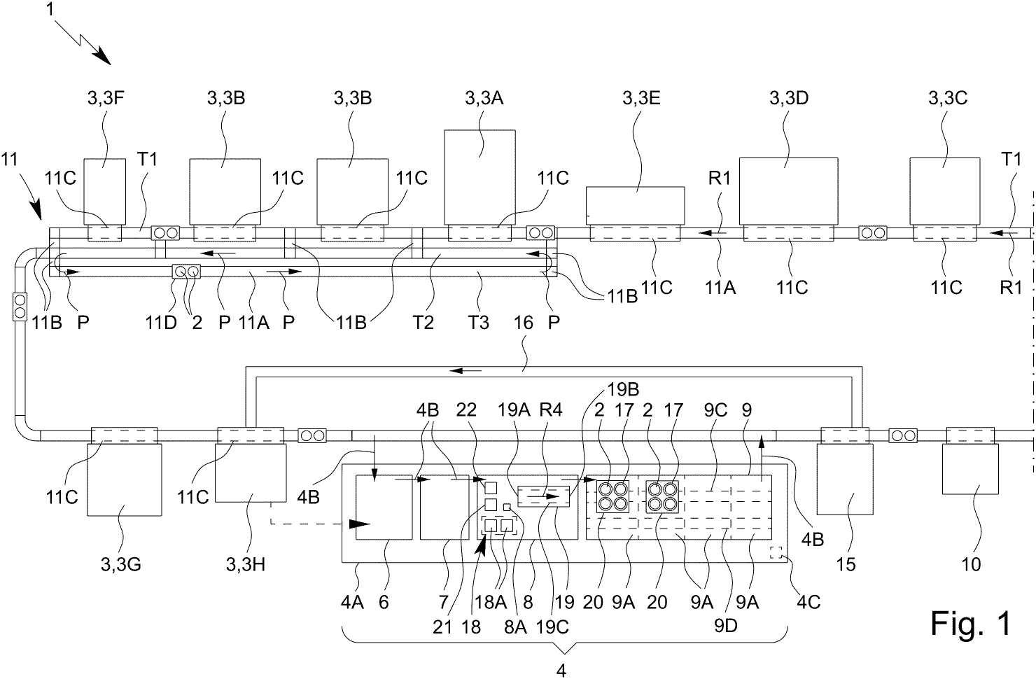

FIG. 1 shows a schematic top view of a processing installation 1 according to the invention for processing spectacle lenses 2.

The processing installation 1 preferably comprises several processing apparatuses 3, in particular operating separately and/or independently of each other. In particular, the processing apparatuses 3 are designed to process and/or produce an optically effective surface or prescription surface - i.e. flat side 2A, 2B - of a spectacle lens 2.

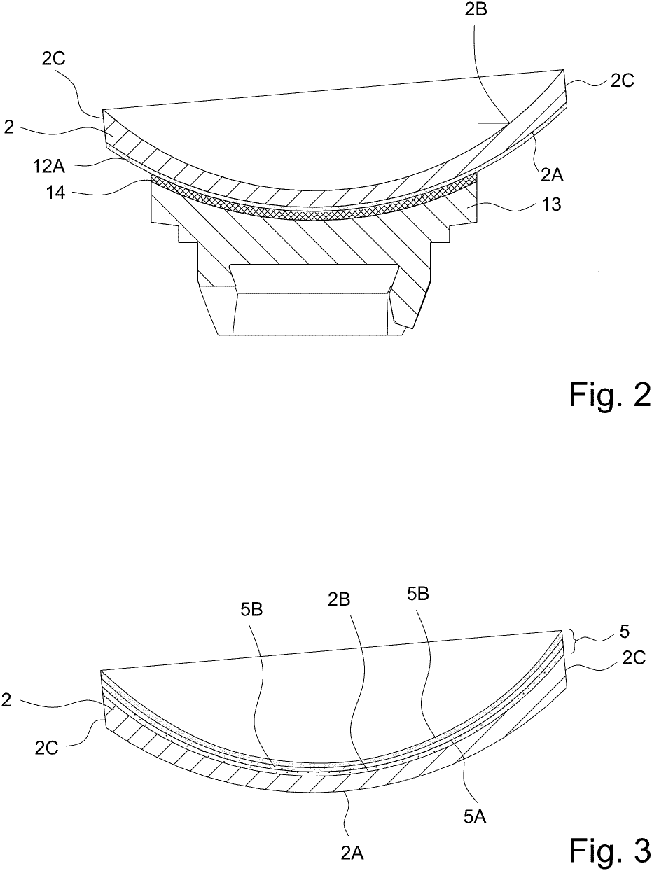

The spectacle lens 2 preferably has a block side or first flat side 2A, a prescription side or second flat side 2B and an edge 2C. This is illustrated in FIGS. 2 and 3. In particular, the second flat side 2A of the spectacle lens 2 is processed or an optically effective surface or prescription surface is generated from the second flat side 2A in the processing installation 1. During the processing, the spectacle lens is held, preferably by means of a block piece 13, on the block side or first flat side 2B.

The first and second flat sides 2A, 2B preferably have an extended area. However, this does not imply that the first and second flat sides 2A, 2B are planar. As shown in FIGS. 2 and 3, the first and second flat sides 2A, 2B are preferably curved.

Preferably, the edge 2C delimits the first and second flat sides 2A, 2B and constitutes a (lateral) boundary of the spectacle lens 2.

The processing installation 1 is preferably designed for simultaneous or parallel processing of several spectacle lenses 2, in particular in different processing apparatuses 3. The processing installation 1 is preferably designed for the complete processing of spectacle lenses 2 and/or for the production of a finished spectacle lens 2 from a lens blank.

The processing installation 1 is preferably designed to completely process spectacle lenses 2, in particular in small batch sizes, in a short time. Preferably, the time in which a spectacle lens 2 passes through the processing installation 1 and/or is completely processed in the processing installation 1 is less than three hours.

The throughput of the processing installation 1 is preferably more than 60 spectacle lenses 2 per hour and/or less than 140 spectacle lenses 2 per hour, in particular about 80 to 120 spectacle lenses 2 per hour.

Preferably, at least one of the processing apparatuses 3 is designed for shape processing/machining, in particular turning (preferably face turning), milling and/or grinding, of spectacle lenses 2. This processing apparatus 3 is hereinafter referred to as the machining apparatus 3A.

Furthermore, preferably at least one of the processing apparatuses 3 is designed for polishing spectacle lenses 2. This processing apparatus 3 is hereinafter referred to as polishing apparatus 3B.

Furthermore, the processing installation 1 preferably comprises a protective layer apparatus 3C for applying a protective layer 12 to spectacle lenses 2, a blocking apparatus 3D for fixing block pieces 13 to spectacle lenses 2, a storage apparatus 3E for stacking or storing spectacle lenses 2, a marking apparatus 3F for marking spectacle lenses 2, a deblocking apparatus 3G for removing the block pieces 13 from the spectacle lenses 2 and/or a cover layer apparatus 3H for applying a cover layer 12B to spectacle lenses 2. Preferably, the apparatuses 3C to 3H each constitute a processing apparatus 3. The apparatuses 3C to 3H will be discussed in more detail later.

Preferably, the processing installation 1 comprises a coating installation 4 according to the proposal or vice versa; in particular, the coating installation 4 according to the proposal is coupled to the processing installation 1.

In particular, parallel, single or paired processing is performed in the processing installation 1 and serial, preferably small group, coating is performed in the coating installation 4.

Preferably, the transport of the spectacle lenses 2 from the processing apparatuses 3 to the coating installation 4, the handover of the spectacle lenses 2 to the coating installation 4 and/or the application of the coating 5 in the coating installation 4 is/are fully automated.

The coating installation 4 is preferably designed to apply a permanent coating 5 to the spectacle lens 2. The coating 5 is in particular transparent to optically visible light.

The coating 5 may comprise or consist of several, in particular different, layers 5A, 5B.

Preferably, the coating 5 comprises a hard layer 5A. Preferably, the hard layer 5A prevents or reduces scratching of the spectacle lens 2.

Furthermore, the coating 5 preferably comprises one or more functional layers 5B. Examples of a functional layer 5B are an anti-reflection layer, an anti-fogging layer, an anti-soiling layer or the like.

Partial reference will be made hereinafter to the hard layer 5A and/or functional layer 5B by referring to them more abbreviated as layer 5A, 5B or layers 5A, 5B, respectively.

The coating 5 and/or hard layer 5A and/or functional layer 5B is/are shown in particular in FIG. 3.

In the following, the expressions “application of a permanent coating” and “coating” or “coating with a permanent coating” are used synonymously and are in particular interchangeable.

The application of the permanent coating 5 is preferably carried out by several steps, in each of which a layer 5A, 5B of the permanent coating 5 is applied to the spectacle lens 2. Different layers 5A, 5B of the coating 5 can be applied in steps that are separate from one another, in particular separated in time and/or space, and in different apparatuses of the coating installation 4.

Preferably, the coating installation 4 comprises several apparatuses for different working steps. Preferably, the coating installation 4 comprises a cleaning apparatus 6 for cleaning spectacle lenses 2, one or more coating apparatuses 7, 9 for applying the permanent coating 5 to spectacle lenses 2, an intermediate storage apparatus 8 for intermediate storage of spectacle lenses 2, in particular after application of a layer 5A, 5B in one of the coating apparatuses 7, 9.

The coating apparatus 7 is preferably configured to apply the hard layer 5A. The second coating apparatus 9 is preferably configured to apply one or more functional layers 5B.

The devices 6 to 9 of the coating installation 4, in particular the cleaning apparatus 6, first coating apparatus 7, intermediate storage apparatus 8 and second coating apparatus 9, are preferably arranged serially and/or linearly one behind the other, in particular in the order mentioned, as shown in particular in FIG. 1. In particular, the devices 6 to 9 are arranged in such a way that each spectacle lens 2 passing through one of the devices 6 to 9 also passes through the other devices 6 to 9. Preferably, it is not possible to selectively feed a spectacle lens 2 to only one apparatus 6 to 9 of the coating installation 4. This allows a simple structure of the coating installation 4, as well as a fast coating of the spectacle lenses 2 in the coating installation 4.

Optionally, the processing installation 1 comprises an edge processing apparatus 10 for edge processing the spectacle lenses 2 or the edge 2C of the spectacle lenses 2. Preferably, the edge processing apparatus 10 is arranged downstream of the coating installation 4. Preferably, the edge processing apparatus 10 is designed to adapt the edge 2C of the spectacle lenses 2 to the shape of a spectacle frame for which the spectacle lenses 2 are intended, so that the spectacle lenses 2 can be inserted into the associated spectacle frame.

The processing installation 1 and/or coating installation 4 preferably has or have a transport system 11 for transporting the spectacle lenses 2 through the processing installation 1 and/or through the coating installation 4 and/or to the individual processing apparatuses 3. The transport system 11 preferably comprises or is formed by one or more conveyor devices 11A, in particular belt conveyors. The conveyor device(s) 11A preferably form(s) one or more transport tracks T1, T2, T3, in particular a first transport track T1, a second transport track T2 and/or a third transport track T3.

The processing installation 1 and/or the transport system 11 is preferably designed for automated transport of the spectacle lenses 2 from the processing apparatuses 3 to the coating installation 4 and/or for, in particular automated, handover of the spectacle lenses 2 to the coating installation 4.

Preferably, the spectacle lenses 2 are arranged or deposited - in particular in pairs in each case - in transport containers 11D and the transport containers 11D are transported with the transport system 11. The transport containers 11D are preferably designed as transport boxes, in particular open at the top.

The transport system 11 preferably has, in particular in the region of the processing apparatus 3A, the polishing apparatus 3B and/or the marking apparatus 3F, a plurality of transport tracks T1, T2, T3, in particular at least two or three transport tracks T1, T2, T3.

The transport tracks T1, T2, T3 preferably run parallel to each other and/or are designed to convey a plurality of spectacle lenses 2 in parallel. “Parallel” in this context does not necessarily mean that the transport tracks T1, T2, T3 run in a straight line and are parallel to each other in a geometric sense, i.e. have a constant distance from each other, but merely that different spectacle lenses 2 or transport containers 11D can be transported or conveyed simultaneously on the transport tracks T1, T2, T3. Nevertheless, the transport tracks T1, T2, T3 are preferably also - at least in sections - rectilinear and preferably (in the geometric sense) parallel to each other.

The first transport track T1 preferably runs directly between or adjacent to the processing apparatuses 3 and/or through the processing apparatuses 3.

In particular, the first transport track T1 is arranged in such a way that a direct or immediate conveyance or transfer of spectacle lenses 2 from a processing apparatus 3 to an adjacent and/or downstream processing apparatus 3 is possible, preferably without the spectacle lenses 2 first having to be fed to another transport track T1, T2, T3.

The transport tracks T1, T2, T3 are preferably connected to each other by changeover devices 11B. The changeover devices 11B allow a transfer of spectacle lenses 2 or transport containers 11D between the transport tracks T1, T2, T3, in particular therefore a transfer of spectacle lenses 2 or transport containers 11D between the first transport track T1 and the second transport track T2 and/or between the second transport track T2 and the third transport track T3. The changeover devices 11B preferably operate transversely, in particular perpendicularly, to the transport tracks T1, T2, T3. The changeover devices 11B may be designed, for example, as sliders or as belt conveyors.

The transport system 11 and/or the transport tracks T1, T2, T3 preferably enable a circulation and/or circular transport of spectacle lenses 2, in particular in the area of the machining apparatus 3A, polishing apparatus 3B and/or marking apparatus 3F. This will be explained in more detail later.

A method for manufacturing and/or processing spectacle lenses 2 in the processing installation 1 preferably comprises the steps explained below. At this point, only a brief overview of the method is to be given. Further details or method steps will be explained in more detail later. Likewise, individual method steps explained below may be omitted as the case may be.

The method is described below with reference to a single spectacle lens 2. Preferably, several spectacle lenses 2 are processed simultaneously in the processing installation 1 in the manner described below.

The processing in the processing apparatuses 3 is preferably carried out on blocked spectacle lenses 2, i.e. spectacle lenses 2 to which a block piece 13 has been attached. In principle, however, the use of block pieces 13 can be dispensed with, i.e. processing without block pieces can be carried out if necessary.

Preferably, a protective layer 12A is applied to the block side or first flat side 2A of the spectacle lens 2 in the protective layer apparatus 3C. In particular, the protective layer 12A serves to protect the block side or first flat side 2A of the spectacle lens 2, which is usually already finished in its shape, from damage during blocking and/or subsequent processing. The protective layer 12A is preferably removable. For example, the protective layer 12A may be configured as a film which is applied and/or adhered to the spectacle lens 2. Preferably, however, the protective layer 12A is made of a curable material, for example a protective lacquer or the like, which is applied to the spectacle lens 2, in particular sprayed on, and is then cured, for example by means of irradiation of the spectacle lens 2 and/or of the protective layer 12A, in particular with UV radiation.

The attachment of the block piece 13 to the spectacle lens 2 is preferably performed in the block apparatus 3D and/or after the application of the protective layer 12A in the protective layer apparatus 3C. Preferably, the block piece 13 is fixed or attached to the spectacle lens 2 by means of a blocking material 14. The attachment of the block piece 13 to the spectacle lens 2 is hereinafter also referred to as blocking the spectacle lens 2, or more abbreviated as blocking. In FIG. 2, the block piece 13 is shown.

After blocking, the spectacle lens 2 is preferably conveyed further to the (optional) storage apparatus 3E. In the storage apparatus 3E, preferably several, in particular blocked, spectacle lenses 2 are stored, in particular stacked. This storage and/or stacking of the blocked spectacle lenses 2 serves in particular to allow the blocking material 14 to cure and/or dry.

After blocking in the blocking apparatus 3D and/or storing in the storage apparatus 3E, a shaping processing/machining of the spectacle lens 2 is preferably carried out in the shaping processing apparatus 3A. Here, preferably the optically effective surface or prescription surface 2B - i.e. the second flat side 2B - of the spectacle lens 2 is processed.

After the spectacle lens 2 has been processed in the processing apparatus 3A, it is preferably polished in the polishing apparatus 3D. Preferably, the processing installation 1 comprises two or more polishing apparatuses 3B. This allows several spectacle lenses 2 to be polished simultaneously in different polishing apparatuses 3B. In this way, the throughput of the processing installation 1 can be increased and the sequence of processing the spectacle lenses 2 can be optimized. Typically, the processing in the maching apparatus 3A requires significantly less time than the polishing in the polishing apparatus 3B, so that by providing several polishing apparatuses 3B, a jam of spectacle lenses 2 in front of the polishing apparatuses 3B can be prevented and the processes in the processing installation 1 can be optimized.

After polishing in the polishing apparatus 3B, the spectacle lens 2 is preferably marked in the marking apparatus 3F, preferably by means of a laser. However, the marking is only optional and can also be omitted.

After a spectacle lens 2 has been processed in the machining apparatus 3A, polishing apparatus 3B and/or marking apparatus 3F, the spectacle lens 2 is preferably transported to the deblocking apparatus 3G. In the deblocking apparatus 3G, if present, the block piece 13 and/or the protective layer 12A are detached from the spectacle lens 2. The removal of the block piece 13 is also referred to as deblocking the spectacle lens 2 or deblocking.

Preferably, after deblocking and/or removal of the protective layer 12A and/or before transport of the spectacle lens 2 to the coating installation 4, a (re)application of a protective layer 12A and/or cover layer 12B to the spectacle lens 2 is performed.

The cover layer 12B is preferably applied to the same flat side 2A, 2B of the spectacle lens 2 to which the protective layer 12A had previously been applied. The cover layer 12B serves to cover a flat side 2A, 2B of the spectacle lens 2 - in particular again the same or first flat side 2A or previous block side - during coating in the coating installation 4, so that no coating is applied to the flat side 2A, 2B of the spectacle lens 2 covered by the cover layer 12B.

It has been shown that after the processing of the spectacle lens 2 in the processing apparatuses 3, the protective layer 12A often already shows slight damage and thus no optimal protection against an undesired coating of the spectacle lens 2 can be guaranteed by the protective layer 12A on the side to which the protective layer 12A is applied. Furthermore, in particular when a spectacle lens 2 is deblocked, i.e. when a block piece is removed or separated from the spectacle lens 2, damage or destruction, in particular partial and/or large-area detachment, of the protective layer 12A occurs. It is therefore advantageous to remove the protective layer 12A before coating the spectacle lens 2 and to apply a new protective layer or cover layer 12B.

Preferably, the different terms “protective layer 12A” and “cover layer 12B” serve only to differentiate between the layer applied for processing in the processing apparatuses 3 (protective layer 12A) and the layer applied for coating in the coating installation 4 (cover layer 12B).

Preferably, the protective layer device 12A and the cover layer device 12B are identical or of the same type. Accordingly, the protective layer apparatus 3C and the cover layer apparatus 3H are preferably also of identical or similar design. Therefore, the application of the cover layer 12B may optionally also be performed in the protective layer apparatus 3C, or the protective layer apparatus 3C may comprise or form the cover layer apparatus 3H, instead of providing a separate cover layer apparatus 3H in addition to the protective layer apparatus 3C.

After the processing of the spectacle lens 2 in the processing apparatuses 3, in particular after the application of the cover layer 12B, the spectacle lens 2 is preferably transferred, in particular automatically, to the coating installation 4 and/or cleaning apparatus 6. The transfer can take place indirectly, in particular via the transport system 11 or one of the transport tracks T1, T2, T3, or directly from one of the processing apparatuses 3, in particular from the deblocking apparatus 3G or cover layer apparatus 3H, as indicated in particular in FIG. 1 by the dashed arrow.

The coating installation 4 preferably comprises a common housing or casing 4A for the apparatuses of the coating installation 4, in particular the cleaning apparatus 6, first coating apparatus 7, intermediate storage apparatus 8 and/or second coating apparatus 9.

Preferably, the spectacle lens 2 is cleaned in the cleaning apparatus 6. Preferably, the cleaning apparatus 6 is designed to clean several spectacle lenses 2 simultaneously.

After cleaning, the spectacle lens 2 is preferably transferred to the first coating apparatus 7 or transported to the first coating apparatus 7.

In the first coating apparatus 7, a first layer or hard coating 5A is preferably applied or deposited on the spectacle lens 2.

Preferably, the spectacle lens 2 is transferred to the intermediate storage apparatus 8 after the application of the hard layer 5A. Preferably, a plurality of spectacle lenses 2 are temporarily stored in the intermediate storage apparatus 8. This serves, in particular, to cure and/or dry the applied hard coating 5A.

Subsequently, the spectacle lens 2 is preferably conveyed and/or transferred to the second coating apparatus 9. In the second coating apparatus 9, one or more further layers or functional layers 5B of the coating 5 are preferably applied to the spectacle lens 2, for example one or more anti-reflective layers and/or an anti-fogging layer.

Preferably, the processing installation 1 and/or coating installation 4 comprises a detaching apparatus 15 for detaching the cover layer 12B. The detaching apparatus 15 is preferably arranged downstream of the second coating apparatus 9.

In principle, however, the detaching apparatus 15 can be omitted and/or the detaching of the cover layer can be carried out in another device, for example the deblocking apparatus 3G or cover layer apparatus 3H.

After the coating 5 has been applied to the spectacle lens 2, the spectacle lens 2 is preferably transferred and/or conveyed to the detaching apparatus 15 (or other device suitable for detaching the cover layer 12B). In the detaching apparatus 15 or other device, the cover layer 12B is preferably removed or detached from the spectacle lens 2.

From the detaching apparatus 15, the spectacle lens 2 can be transported to further devices of the processing installation 1 and/or coating installation 4, for example the edge processing apparatus 10, which are arranged downstream of the detaching apparatus 15. This is particularly the case if only one flat side 2A, 2B, in particular the prescription surface, of the spectacle lens 2 is to be coated with a coating 5.

However, if the other flat side 2A, 2B of the spectacle lens 2 is also to be coated with a coating 5, the spectacle lens 2 is preferably transported back to the cover coating apparatus 3H. For this purpose, the processing installation 1 and/or coating installation 4 preferably comprises a return transport apparatus 16.

Thus, if the spectacle lens 2 is to be coated on both sides, the spectacle lens 2 is preferably conveyed back to the cover layer apparatus 3H arranged upstream of the coating installation 4, after a first pass through the coating installation 4 and/or after the application of the coating 5 in the coating installation 4, in particular by means of the return transport apparatus 16, the spectacle lens 2 is preferably conveyed back to the cover layer apparatus 3H arranged upstream of the coating installation 4 and is coated again with a cover layer 12B in the cover layer apparatus 3H, the cover layer 12B being applied to the side of the spectacle lens 2 to which the coating 5 was previously applied in the coating installation 4. Subsequently, in the coating installation 4, a further permanent coating 5 is applied to the flat side 2A, 2B not yet provided with the desired coating 5, in particular to the first flat side 2A or block side, and preferably after coating the cover layer 12B is detached in the detaching apparatus 15.

In summary, therefore, preferably the spectacle lenses 2 are first processed, in particular shaping and/or in the processing apparatuses 3. In this respect, preferably several spectacle lenses 2 are processed simultaneously in different processing apparatuses 3. Thus, preferably a parallel processing of spectacle lenses 2 takes place. Preferably, a circulation of spectacle lenses 2 takes place.

Subsequently, the permanent coating 5 is preferably applied to the spectacle lenses 2. Here, the spectacle lenses 2 are preferably coated serially or one after the other. The application of the coating 5 is carried out in particular in the coating installation 4.

Preferably, the application of the coating 5 comprises several steps.

In particular, the spectacle lenses 2 are first cleaned in a - optional - step first.

Preferably, a hard layer 5A of the permanent coating 5 is applied to the spectacle lenses 2, in particular after cleaning.

Preferably, the hard layer 5A is cured after application, in particular in several or separate steps, which may in particular be carried out in different devices. Preferably, the curing comprises an irradiation of the spectacle lenses 2 with electromagnetic radiation, in particular UV radiation, and a (further) drying and/or further curing by heating of the spectacle lenses 2. Preferably, the hard layer 5A dries at least substantially already during the irradiation of the spectacle lenses 2 with electromagnetic radiation, at least to such an extent that a further transport of the spectacle lenses 2 is possible without damaging the (not yet fully cured) hard layer 5A.

Preferably, in particular after application of the hard layer 5A, one or more further functional layers 5B of the coating 5 are applied to the spectacle lenses 2, preferably in a vacuum and/or by means of sputtering.

### Parallel Processing

The processing installation 1 is preferably designed to process several spectacle lenses 2 simultaneously. In particular, the processing installation 1 is thus designed for parallel processing of spectacle lenses 2.

The processing installation 1 is preferably configured as described in WO 2013/131656 A2, WO 2017/080639 A1, WO 2017/202502 A1 and/or WO 2018/153787 A1. The combination of the processing installation explained in these documents with the coating installation 4 forms an independently realizable aspect of the present invention.

The processing of the spectacle lenses 2 in the processing installation 1 is preferably carried out individually or in pairs. In particular, the processing sequence in the processing installation 1 is thus determined individually for a single spectacle lens 2 or for a pair of spectacle lenses 2 in each case. It is therefore possible that the various spectacle lenses 2 or pairs of spectacle lenses 2 pass through the processing apparatuses 3 in different sequences and/or are processed in different processing apparatuses 3.

Preferably, the processing installation 1 comprises a plurality of separate and/or independently operating processing apparatuses 3.

The processing installation preferably has several processing apparatuses 3 of the same kind or construction. In particular, for each type of processing or each processing step -for example for blocking, turning, milling, polishing, marking and/or deblocking - several processing apparatuses of the same kind or construction can be provided.

Preferably, the processing installation 1 comprises at least one machining apparatus 3A. However, the processing installation 1 may also comprise two or more machining apparatuses 3A.

Preferably, the processing installation 1 comprises at least one polishing apparatus 3B. Particularly preferably, the processing installation 1 comprises two, three, four or more polishing apparatuses 3B.

Preferably, the processing installation 1 or the transport system 11 comprises one or more transport tracks T1, T2, T3. The transport tracks T1, T2, T3 are preferably part of the transport system 11 or form the transport system 11.

The transport system 11 is designed in such a way that parallel processing of spectacle lenses 2 is possible in the processing installation 1. In particular, the spectacle lenses 2 can be selectively conveyed by means of the transport system 11 to one of a plurality of similar processing apparatuses 3 and/or the spectacle lenses 2 can be conveyed past one or more processing apparatuses 3.

Preferably, the spectacle lenses 2 are transported by means of the transport system 11 in transport containers 11D and/or in pairs and/or are fed to individual processing apparatuses 3 by means of the transport system 11.

For better differentiation, the transport tracks T1, T2, T3 are designated as first transport track T1, second transport track T2 and third transport track T3. However, the transport tracks T1, T2, T3 preferably have the same structure. Statements regarding the first transport track T1 therefore preferably also apply to the second transport track T2 and/or the third transport track T3, even if this is not explicitly mentioned.

The first transport track T1 is preferably straight at least in sections. Preferably, the first transport track T1 has several separate conveyor devices 11A, which are arranged in particular one behind the other and/or form a continuous transport track.

Preferably, the first transport track T1 connects the machining apparatus(es) 3A and the polishing apparatus(es) 3B to each other. Preferably, the first transport track T1 is arranged between the processing apparatuses 3 in such a way that by means of the transport track T1 a direct transport of a spectacle lens 2 from a processing apparatus 3 to a processing apparatus 3 immediately downstream of this processing apparatus 3 is possible without the spectacle lens 2 leaving the first transport track T1. Preferably, the transport track T1 thus establishes a direct connection between several processing apparatuses 3.

Preferably, the first transport track T1 connects the protective layer apparatus 3C, the blocking apparatus 3D, the storage apparatus 3E, the machining apparatus(es) 3A, the polishing apparatus(es) 3B, and/or the marking apparatus 3F to each other.

The first transport track T1 optionally passes through a plurality of the processing apparatuses 3, in particular the protective layer apparatus 3C, blocking apparatus 3D, storage apparatus 3E, machining apparatus(es) 3A, polishing apparatus(es) 3B,and/or marking apparatus 3F.

Preferably, the processing apparatuses 3 or 3A to 3F each have their own conveyor device 11C. The conveyor device 11C is preferably integrated into the respective processing apparatus 3 or is an integral component of the respective processing apparatus 3. Particularly preferably, the respective conveyor device 11C is designed as a belt conveyor.

Preferably, the first transport track T1 is formed by conveying devices 11C of the processing apparatuses 3 and further conveying devices 11A and, in particular, in this case the conveying devices 11A are arranged between the processing apparatuses 3D and/or the conveying devices 11A together with the conveying devices 11C of the processing apparatuses 3 form an uninterrupted and/or continuous, in particular rectilinear, transport track.

The first transport track T1 preferably has a transport direction R1 and/or is configured to transport the spectacle lenses 2 in the transport direction R1.

The second transport track T2 preferably runs next to the first transport track T1 and/or parallel to the first transport track T1. Preferably, the second transport track T2 runs past one or more processing apparatuses 3. In particular, the second transport track T2 passes the machining apparatus 3A or apparatuses 3A, the polishing apparatus 3B or apparatuses 3B and/or the marking apparatus 3F or apparatuses 3F.

The second transport track T2 is preferably designed for transporting spectacle lenses 2 past one or more processing apparatuses 3. In particular, spectacle lenses 2 are transportable by means of the second transport track T2 past spectacle lenses 2 which are transported on the first transport track T1. In other words, the second transport track T2 is configured for passing spectacle lenses 2 on the first transport track T1.

The second transport track T2 preferably has a transport direction R2 and/or is designed to transport the spectacle lenses 2 in the transport direction R2. Preferably, the transport direction R2 of the second transport track T2 is parallel and/or identical to the transport direction R1 of the first transport track T1. In principle, however, it is also possible that the first transport track T1 and the second transport track T2 have different and/or opposite transport directions R1, R2 and/or that the first and second transport tracks T1, T2 form a circuit for the spectacle lenses 2.

Preferably, the second transport track T2 is connected to the first transport track T1 via one or more changeover devices 11B. In particular, the changeover devices 11B allow a change from the first transport track T1 to the second transport track T2 and/or vice versa.

The changeover devices 11B are preferably arranged transversely to the first and/or second transport track T1, T2 and/or are configured for transporting spectacle lenses 2 transversely, in particular perpendicularly, to the transport direction R1 and/or R2.

Particularly preferably, a changeover device 11B is arranged in each case between two processing apparatuses 3, so that a changeover from the first transport track T1 to the second transport track T2 and/or vice versa is possible in each case before and/or after a processing apparatus 3. In this way, the spectacle lenses 2 can be flexibly fed in a targeted manner to individual processing apparatuses 3 by changing from the second transport track T2 to the first transport track T1 immediately upstream of the corresponding processing apparatus 3 and then being conveyed to the processing apparatuses 3. Alternatively or additionally, a spectacle lens 2 can be discharged from the transport track T1 and/or transported past one or more subsequent processing apparatuses 3 after processing in a processing apparatus 3 by transporting the spectacle lens 2 to the second transport track T2 and past one or more processing apparatuses 3 on the second transport track T2 by means of a changeover device 11B.

The third transport track T3 preferably runs next to and/or parallel to the first and/or second transport track T1, T2. Preferably, the third transport track T3 forms a circuit with the first and/or second transport track T1, T2. In particular, the third transport track T3 is connected to the second transport track T2 via two or more changeover devices 11B.

The third transport track T3 is preferably configured to transport the spectacle lenses 2 past one or more processing apparatuses 3.

The third transport track T3 preferably has a transport direction R3. The transport direction R3 is preferably opposite to the first and/or second transport direction R1, R2.

Preferably, a changeover device 11B arranged between the first and second transport tracks T1, T2 and a changeover device 11B arranged between the second and third transport tracks T2, T3 are arranged, in particular at the same height, in such a way that a direct transport of spectacle lenses 2 from the first transport track T1 to the third transport track T3 and/or vice versa is made possible without a transport of the spectacle lens 2 in the transport direction R2 taking place on the second transport track T2.

The third transport track T3 is preferably arranged at least in the region of the machining apparatus(es) 3A, the polishing apparatus(es) 3B and/or the marking apparatus 3F, so as to allow a circulation of spectacle lenses 2 in the region of said apparatuses 3. In other words, the transport system 11 preferably allows a circulation of spectacle lenses 2, in particular by means of the second and/or third transport track T2, T3 and/or in the area of the machining apparatus(es) 3A, the polishing apparatus(es) 3B and/or the marking apparatus 3F.

In particular, the transport tracks T1, T2, T3 form one or more rings, preferably so that ring conveying and/or circulation is possible. This is indicated in particular in FIG. 1 by the arrows P.

In the embodiment shown in FIG. 1, the third transport track T3 is arranged exclusively in the region of the machining apparatus(es) 3A, the polishing apparatus(es) 3B and/or the marking apparatus 3F, so that in this region a circulation and/or circular conveying of spectacle lenses 2 and thus a flexible processing and feeding of spectacle lenses 2 to individual processing apparatuses 3 is possible. In the region of the protective layer apparatus 3C, blocking apparatus 3D, storage apparatus 3E, deblocking apparatus 3G and/or cover layer apparatus 3H, the processing installation 1and/ or the transport system 11 preferably has only one transport track T1, T2, T3 in order to keep the complexity of the processing installation 1 and/or the transport system 11 as low as possible. In this way, an overall simple structure and, in the area of the machining apparatus 3A, polishing apparatus 3B and/or marking apparatus 3F, an increased flexibility are achieved.

Preferably, the deblocking apparatus 3G, cover layer apparatus 3H, coating installation 4, detaching apparatus 15 and/or edge processing apparatus 10 are connected to each other by at least or exactly one transport track T1, T2, T3, in particular the first transport track T1. Optionally, the (first) transport track T1, T2, T3 runs through the deblocking apparatus 3G, cover layer apparatus 3H, coating installation 4, detaching apparatus 15 and/or edge processing apparatus 10.

Preferably, one of the transport tracks T1, T2, T3, preferably the second transport track T2, connects the deblocking apparatus 3G, cover layer apparatus 3H, coating installation 4, detaching apparatus 15 and/or edge processing apparatus 10 to one another and/or passes through one or more of these apparatuses. Particularly preferably, the transport track T1, T2, T3 runs linearly and/or rectilinearly in the region of the deblocking apparatus 3G, cover layer apparatus 3H, coating installation 4, detaching apparatus 15 and/or edge processing apparatus 10.

In particular, one, here the second, transport track T2 is curved and/or the second transport track T2 runs in a U-shape, as shown in particular in FIG. 1. This enables a compact or space-saving design of the processing installation 1.

Preferably, the processing installation 1 comprises a continuous and/or uninterrupted transport track. This continuous transport track is in particular formed by the transport track T1 and one of the transport tracks T2, T3 and one or more changeover devices 11B. In the illustrated example according to FIG. 1, a continuous transport track and/or a transport track passing through or connecting all apparatuses of the processing installation 1 and/or coating installation 4 is formed by a section of the transport track T1, a changeover device 11B and the second transport track T2.

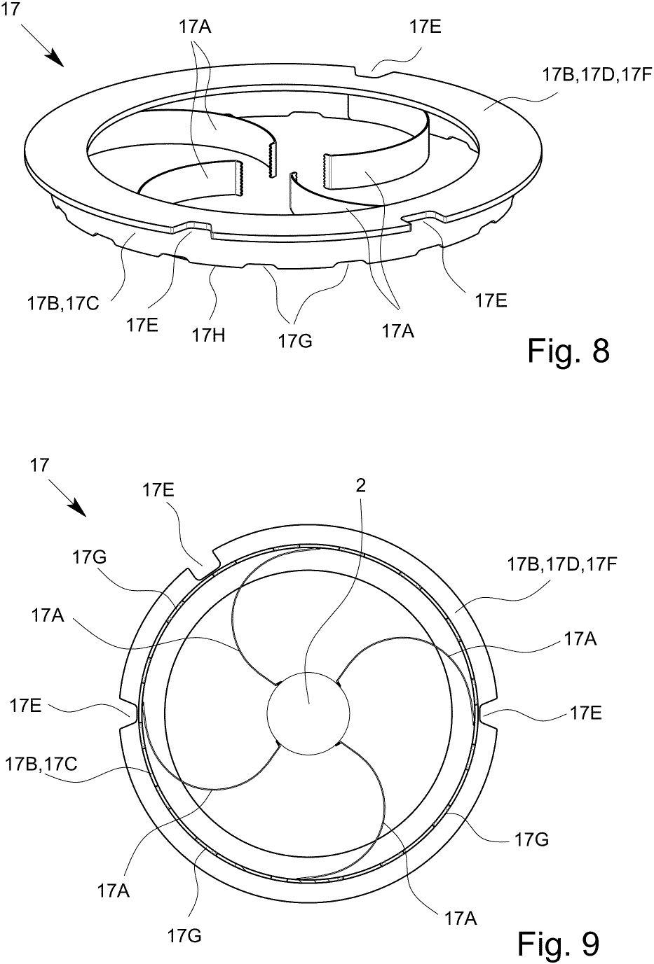

The processing installation 1 may optionally also comprise two or more groups or rows of processing apparatuses 3, which are in particular arranged opposite each other and/or arranged in such a way that the associated transport tracks T1 and/or T2 of the two groups preferably run parallel to each other. In particular, the processing installation 1 may be designed as explained or illustrated in FIG. 8 and/or p. 35, line 21 to p. 38, line 2 of WO 2013/131656 A2.

### Coating Installation

The coating installation 4 is preferably designed for processing and/or coating spectacle lenses 2 in small batch sizes, in particular batch sizes of four, six or eight spectacle lenses 2.

The coating installation 4 is preferably designed for the serial coating of spectacle lenses 2, in particular in groups or batches of the batch size mentioned. In this case, the above definition of “serial processing” applies accordingly to the “serial coating”, in particular in the coating installation 4. The devices 6 to 9 of the coating installation 4, which are explained in more detail below, each represent a processing device in this case.

Preferably, the coating installation 4 represents an independently realizable aspect of the present invention, which in particular is also realizable independently of the features of the processing installation 1 described above.

The coating installation 4 preferably comprises an (automated) handling system 4B for (automated) handling of the spectacle lenses 2. Alternatively or additionally, the coating installation comprises at least one, preferably several, coating apparatuses 7, 9, in particular this is also possible or realizable independently of the handling system 4B. The features, characteristics and aspects of the coating installation 4 explained in more detail below can preferably be implemented independently of one another and can in particular be advantageous both independently of one another and in various combinations, or form independent inventions.

Preferably, the coating installation 4 is designed in such a way that spectacle lenses 2 pass serially through the devices 6 to 9 of the coating installation 4. In particular, it is thus provided that the coating installation 4 comprises exactly one device for each step of the coating process. Nevertheless, the devices 6 to 9 of the coating installation 4 are each preferably designed to process several spectacle lenses 2 simultaneously. However, in contrast to the parallel processing which takes place in the processing installation 1 and/or prior to coating in the coating installation 4, the coating installation 4 preferably comprises only (exactly) one apparatus 6 to 9 for each working step. Preferably, therefore, the spectacle lenses 2 pass through all the devices 6 to 9 of the coating installation 4.

The coating installation 4 preferably comprises a/exactly one cleaning apparatus 6, a/exactly one first coating apparatus 7, an/exactly one intermediate storage apparatus 8 and/or a/exactly one second coating apparatus 9.

The devices 6 to 9 are preferably arranged in series and/or along a (straight) line.

The coating installation 4 is preferably adapted to apply a permanent coating 5 to the spectacle lenses 2. The permanent coating 5 may comprise or consist of several layers 5A, 5B.

The coating installation 4 preferably comprises a common housing or a common casing 4A for the cleaning apparatus 6, first coating apparatus 7, intermediate storage apparatus 8, and/or second coating apparatus 9.

The coating installation 4 is preferably directly connected to the transport system 11. Preferably, the coating installation 4 is arranged parallel to one of the transport tracks T1, T2, T3 and/or adjacent to one of the transport tracks T1, T2, T3. Optionally, the coating installation 4 comprises the transport system 11 or at least a part or section of the transport system 11 or forms such. In particular, one of the transport tracks may pass through the coating installation 4.

The coating installation 4 and/or its devices 6 to 9 is or are preferably designed to remove spectacle lenses 2 from the transport system 11 for and/or before coating, and/or to transfer them to the transport system 11 after coating, in particular in an automated manner.

The transport system 11 is preferably configured to further transport transport containers 11D, in which the spectacle lenses 2 are transported by the transport system 11, during the coating of spectacle lenses 2 in the coating installation 4, so that the spectacle lenses 2 can be deposited back into the transport containers 11D after coating in the coating installation 4.

Optionally, the transport system 11 may also be designed for (intermediate) storage of transport containers 11D, for example by means of one or more storage apparatus(es) designed for this purpose. The storage apparatus(es) can, for example, be arranged or provided laterally next to, above and/or below the transport track T1, T2, T3.

The coating installation 4 as a whole and/or individual apparatuses 6 to 9, in particular thus the cleaning apparatus 6, first coating apparatus 7, intermediate storage apparatus 8 and/or second coating apparatus 9, preferably has/have a cleanroom or cleanrooms separate from one another in each case and/or is/are (in each case) designed as a cleanroom or arranged therein. The cleanroom is preferably (in each case) a cleanroom according to ISO class 7 or 8 according to DIN EN ISO 14644-1:2015.

This prevents dirt particles, such as dust or the like, from being deposited on the lens 2 during coating in the coating installation 4.

The coating installation 4 may also comprise the cover layer apparatus 3H and/or the detaching apparatus 15. However, the cover layer apparatus 3H and/or the peeling device 1 is/are preferably arranged outside the casing 4A.

The cleaning apparatus 6, first coating apparatus 7, intermediate storage apparatus 8 and/or second coating apparatus 9 are preferably arranged directly adjacent to one another and/or directly behind one another, in particular in a row or line. In particular, the coating installation 4 is designed for the direct transfer of spectacle lenses 2 between adjacent apparatuses 6 to 9. For this purpose, the coating installation 4 preferably comprises a handling system 4B, in particular an automated handling system 4B. In particular, the coating installation 4 and/or the handling system 4B is designed for the direct transfer of spectacle lenses 2 from the cleaning apparatus 6 to the first coating apparatus 7, from the first coating apparatus 7 to the intermediate storage apparatus 8 and/or from the intermediate storage apparatus 8 to the second coating apparatus 9. This allows spectacle lenses 2 to pass quickly through the coating installation 4.

The handling system 4B is preferably designed both for handling spectacle lenses 2 and for handling holders, in particular clamping rings 17, for temporarily holding the spectacle lenses 2. In particular, the handling system 4B enables a fully automated passage through the coating installation 4.

In the illustrative examples, the holders for the spectacle lenses 2 are designed in particular as clamping rings 17. However, this is not mandatory. In principle, the holders can also be designed differently, for example as grippers, suction cups or the like. In particular, the term “clamping ring” can therefore also be replaced by the term “holder”.

The holders/clamping rings 17 are preferably designed to hold the spectacle lenses 2 in such a way that a flat side 2A, 2B, in particular the flat side 2A, 2B to be coated, remains free or is (completely) coatable. In particular, the holders/clamping rings 17 are designed for holding spectacle lenses 2 on the side or on the edge, that is to say for holding on the edge 2C, and/or for one-sided holding spectacle lenses 2 on a flat side 2A, 2B.

In particular, a handling system in the sense of the present invention is understood as the totality of all devices and/or apparatuses by means of which spectacle lenses and/or holders/clamping rings 17 are at least temporarily held, handled and/or transferred between the various apparatuses 6 to 9 in the coating installation 4.

Preferably, the handling system 4B comprises a plurality of devices operating independently of each other. Preferably, the apparatuses 6 to 9 each comprise one or more handling devices for handling spectacle lenses 2 and/or holders/clamping rings 17. These handling devices preferably together form the handling system 4B and/or are coordinated with each other in such a way that a fully automated transfer between the apparatuses 6 to 9 and/or a fully automated passage of spectacle lenses 2 through the coating installation 4 is made possible and/or takes place.

The coating installation 4 and/or the handling system 4B and/or the devices 6 to 9 is/are thus designed for fully automated handling, cleaning, coating and/or transporting of the spectacle lenses 2 in the coating installation 4 and/or the apparatuses 6 to 9. In particular, all work steps in the coating installation 4 and/or in and/or between the individual apparatuses 6 to 9 are fully automated.

### Cleaning Apparatus

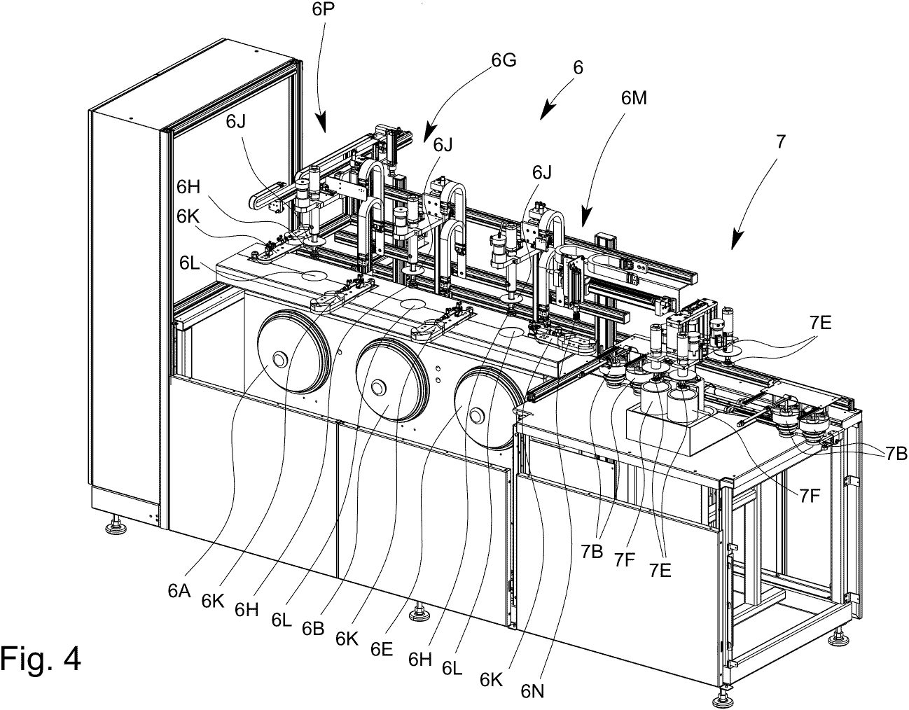

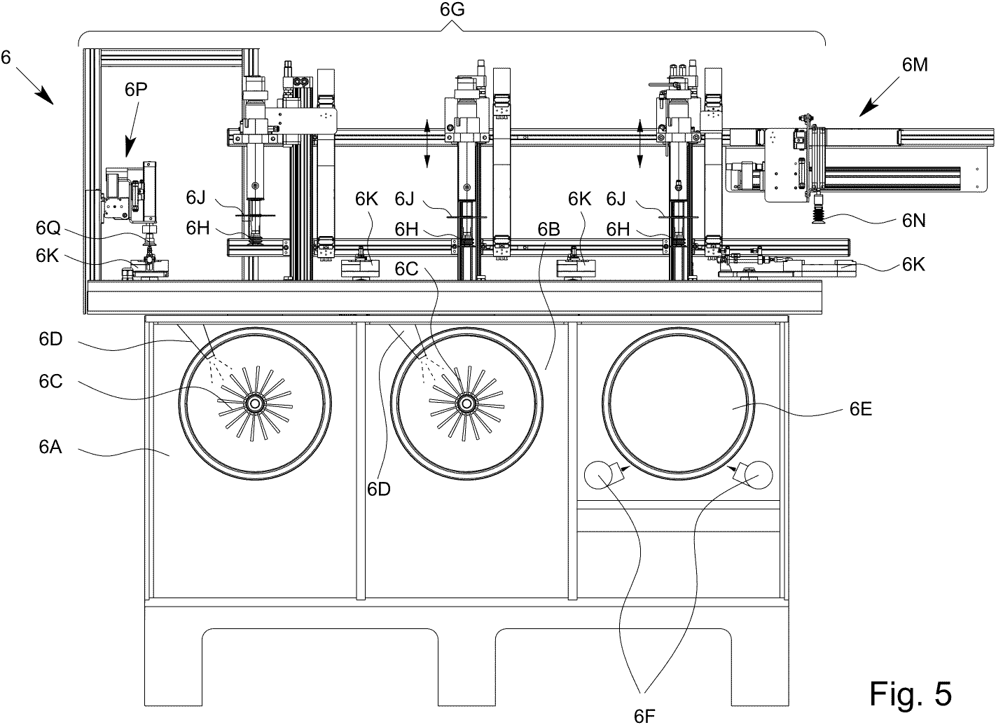

The cleaning apparatus 6 is shown in particular in FIGS. 4 and 5. FIG. 4 shows a schematic perspective view of the cleaning apparatus 6 and first coating apparatus 7, while FIG. 5 shows a schematic side view of the cleaning apparatus 6.

Preferably, the cleaning apparatus 6 is configured for cleaning spectacle lenses 2 by mechanical cleaning, for example by brushing, and/or by chemical cleaning, for example washing the spectacle lenses 2 with a cleaning fluid. Preferably, the cleaning apparatus 6 is configured for simultaneously cleaning a plurality of spectacle lenses 2.

Preferably, the cleaning apparatus 6 comprises at least one cleaning chamber 6A, 6B. In the illustrated example, the cleaning apparatus 6 comprises a first cleaning chamber 6A and a second cleaning chamber 6B.

Preferably, the first cleaning chamber 6A comprises a brush 6C. Preferably, the cleaning apparatus 6 is adapted to clean a spectacle lens 2 in the first cleaning chamber 6A mechanically and/or by means of the brush 6C. In particular, the cleaning in the first cleaning chamber 6A represents a preliminary cleaning.

Optionally, the first cleaning chamber 6A may comprise, in particular in addition to the brush 6C, an applicator 6D for applying a cleaning fluid to the spectacle lens 2. The applicator 6D is preferably configured as a nozzle and/or configured to spray the cleaning fluid onto the spectacle lens 2. The cleaning fluid may comprise or consist of, in particular deionized, water and/or a cleaning chemical.

The second cleaning chamber 6B preferably has the same characteristics as the first cleaning chamber 6A. The preceding explanations regarding the first cleaning chamber 6A therefore preferably also apply to the second cleaning chamber 6B.

The first and/or second cleaning chamber 6A, 6B may also comprise (respectively) two or more brushes 6C so that both flat sides 2A, 2B of the spectacle lens 2 can be cleaned simultaneously.

Preferably, in the first cleaning chamber 6A, a prewashing is carried out, in particular mechanically and/or with the brush 6C. Preferably, in the second cleaning chamber 6B, a post-washing is carried out, in particular a chemical cleaning and/or a cleaning by means of the applicator 6D and/or a cleaning fluid.

Preferably, the cleaning apparatus 6 comprises a drying device 6E. Preferably, the drying device 6E comprises or is formed by a drying chamber. Preferably, the drying device 6E and/or the drying chamber comprises a blower/fan 6F. In particular, the blower/fan 6F is configured to generate an air flow, preferably a warm air flow, for drying the spectacle lens 2.

The first cleaning chamber 6A, the second cleaning chamber 6B and/or the drying device 6E are preferably spatially separated from each other and/or each comprise chambers separated from each other, in particular by walls.

Preferably, the first cleaning chamber 6A, the second cleaning chamber 6B and/or the drying device 6E (respectively) comprise an opening 6L through which a spectacle lens 2 is or can be fed to the cleaning chamber 6A, 6B and/or the drying chamber.

The cleaning apparatus 6 and/or the handling system 4B preferably comprises a handling device 6G, hereinafter referred to in particular as first handling device 6G.

The first handling device 6G preferably forms part of the handling system 4B. Further handling devices of the handling system 4B will be explained below.

For ease of differentiation, these handling devices are referred to as “first handling device”, “second handling device”, and so on. However, these designations only serve to distinguish the individual handling devices of the handling system 4B and do not imply any order or ranking of the handling devices. In particular, the handling system 4B may for example also comprise a third handling device without the handling system 4B comprising a first and/or second handling device. Therefore, for example, a third handling device may be claimed or recited in the claims without the claim also comprising a feature relating to a first and/or second handling device.

In particular, the apparatuses 6 to 9 may each comprise one or more of the handling devices of the handling system 4B, and/or the handling devices of the handling system 4B may each be associated with individual apparatuses 6 to 9.

The first handling device 6G is preferably configured for handling and/or holding one or more spectacle lenses 2 in the cleaning apparatus 6. In particular, the first handling device 6G is configured for holding one or more spectacle lenses 2 during a cleaning process.

The first handling device 6G is preferably configured to transfer spectacle lenses 2 between the first cleaning chamber 6A, the second cleaning chamber 6B and/or the drying device 6E.

Preferably, the first handling device 6G comprises a plurality of separate and/or structurally distinct components which together form the first handling device 6G and/or are coordinated with each other and/or cooperate with each other to handle the spectacle lenses 2 in the cleaning apparatus 6.

The first handling device 6G is preferably configured for holding spectacle lenses 2 in the first and/or second cleaning chamber 6A, 6B and/or the drying device 6E and/or for holding spectacle lenses 2 during cleaning and/or drying.

Preferably, the first handling device 6G comprises at least one holder 6H for this purpose. The holder 6H is preferably designed to hold a spectacle lens 2 on a flat side 2A, 2B and/or comprises a suction cup.

Preferably, the holder 6H is vertically movable. The holder 6H is preferably designed to introduce the spectacle lens 2, in particular vertically from above, into the cleaning chamber 6A, 6B and/or the drying device 6E, to hold it there during cleaning or drying and to move the spectacle lens 2 out of the cleaning chamber 6A, 6B or the drying device 6E again after cleaning or drying.

The holder 6H preferably has a cover 6J for covering and/or closing the opening 6L of the cleaning chamber 6A, 6B and/or the drying device 6E through which the spectacle lens 2 is inserted with the holder 6H into the cleaning chamber 6A, 6B or the drying device 6E.

Preferably, the cleaning chamber 6A, the second cleaning chamber 6B and/or the drying device 6E are each assigned their own holder 6H. The holders 6H are preferably identical in construction.

The cleaning apparatus 6 and/or first handling device 6G preferably comprises at least one handover device 6K.

The handover device 6K is preferably configured for transferring a spectacle lens 2 between two holders 6H, in particular between the holder 6H associated with the first cleaning chamber 6A and the holder 6H associated with the second cleaning chamber 6B.

Preferably, the handover device 6K is arranged between the first cleaning chamber 6A and the second cleaning chamber 6B and/or is configured to take over a spectacle lens 2 from the holder 6H associated with the first cleaning chamber 6A and/or to hand it over to the holder 6H associated with the second cleaning chamber 6B.

The handover device 6K is preferably designed to center the spectacle lens 2. In particular, this makes it possible to avoid or reduce handling errors that occur, for example, when the spectacle lens 2 held on the holder 6H is slightly displaced during cleaning in one of the cleaning chambers 6A, 6B.

The handover device 6K is preferably pivotable. In particular, the handover device 6K is pivotable between a first position, in which the handover device 6K is preferably arranged above the opening 6L of the first cleaning chamber 6A and/or below the holder 6H associated with the first cleaning chamber 6A, and a second position, in which the handover device 6K is preferably arranged above the opening 6L of the second cleaning chamber 6B and/or below the holder 6H associated with the second cleaning chamber 6B. Preferably, the handover device 6K is pivotable between these positions by 180°, in particular about a vertical axis.

The transfer of a spectacle lens 2 from the first cleaning chamber 6A to the second cleaning chamber 6B preferably takes place in that the holder 6H assigned to the first cleaning chamber 6A hands over the spectacle lens 2 to the handover device 6K, in particular deposits it in the handover device 6K, the handover device 6K is pivoted from the first to the second position and, if necessary, centers the spectacle lens 2 in the process, and finally, in the second position, the holder 6H assigned to the second cleaning chamber 6B takes over the spectacle lens 2 from the handover device 6K.

In addition to the handover device 6K described above, the cleaning apparatus 6 and/or first handling device 6G preferably comprises a second handover device 6K for transferring a spectacle lens 2 between the holder 6H associated with the second cleaning chamber 6B and the holder 6H associated with the drying device 6E.

The second handover device 6K is preferably arranged between the second cleaning chamber 6B and the drying device 6E and/or configured to take over a spectacle lens 2 from the holder 6H associated with the second cleaning chamber 6B and/or to hand it over to the holder 6H associated with the drying device 6E. The second handover device 6K is preferably pivotable, in particular between a first position, in which the second handover device 6K is preferably arranged above the opening 6L of the second cleaning chamber 6B and/or below the holder 6H associated with the second cleaning chamber 6B, and a second position, in which the second handover device 6K is preferably arranged above the opening 6L of the drying device 6B and/or of the drying chamber and/or below the holder 6H associated with the drying device 6E.

Preferably, the coating installation 4 and/or the handling system 4B comprises a transfer device 6M for transferring spectacle lenses 2 between the cleaning apparatus 6 and the first coating apparatus 7.

The transfer device 6M preferably comprises a holder 6N for a spectacle lens 2. The holder 6N preferably comprises or is formed by a suction cup.

The cleaning apparatus 6 and/or the handling system 4B is preferably configured for handling, in particular directly and/or fully automatically, spectacle lenses 2 in the cleaning apparatus 6 and/or handing over spectacle lenses 2 to the first coating apparatus 7, in particular by means of the transfer device 6M.

Preferably, the cleaning apparatus 6 and/or the first handling device 6G comprises a further or third handover device 6K for transferring a spectacle lens 2 from the holder 6H associated with the drying device 6E to the transfer device 6M.

Preferably, the third handover device 6K is arranged downstream of the drying device 6E and/or between the drying device 6E and the first coating apparatus 7.

The third handover device 6K is preferably pivotable, in particular between a first position in which the third handover device 6K is preferably arranged above the opening 6L of the drying chamber and/or below the holder 6H associated with the drying chamber, and a second position in which the third handover device 6K is preferably arranged below the transfer device 6M and/or the holder 6N.

The handover devices 6K described are preferably identical in construction.

The transfer device 6M and/or the holder 6N is preferably arranged and/or movable horizontally and/or between the cleaning apparatus 6 / the third handover device 6K and the first coating apparatus 7 / a handling device 7A of the first coating apparatus 7, described in more detail below.

Preferably, spectacle lenses 2 are transferred directly from the first handling device 6A to the first coating apparatus 7 or the handling device 7A of the first coating apparatus 7.

In particular, this is done by, when the spectacle lens 2 with the holder 6H has been moved out of the drying chamber, first arranging the third handover device 6K above the opening 6L and/or below the holder 6H associated with the drying device 6E, handing over the spectacle lens 2 to the third handover device 6K, and then pivoting the third handover device 6K to a position in which the spectacle lens 2 is taken over with the holder 6N. The holder 6N then removes the spectacle lens 2 from the third handover device 6K, moves to a position in which the spectacle lens 2 can be handed over to the second coating apparatus 7 or the handling device 7A, and hands over the spectacle lens 2 to the first coating apparatus 7 or the handling device 7A.

Preferably, the cleaning apparatus 6 is directly connected to the transport system 11 and/or connected to one of the transport tracks T1, T2, T3. In particular, the cleaning apparatus 6 is configured for removing spectacle lenses 2 from the transport system 11 and/or from one of the transport tracks T1, T2, T3 and/or from a transport container 11D and/or directly from the cover layer apparatus 3H.

The coating installation 4 and/or the cleaning apparatus 6 and/or the handling system 4B and/or the first handling device 6G preferably comprises a (further) transfer device 6P for transferring spectacle lenses 2 from the transport system 11 to the coating installation 4 and/or the cleaning apparatus 6.

The transfer device 6P preferably comprises a holder 6Q for a spectacle lens 2. The holder 6Q preferably comprises or is formed by a suction cup.

The holder 6Q is preferably movable or traversable horizontally and/or along the transfer device 6P. The transfer device 6P preferably extends at least substantially transversely, in particular perpendicularly, to the transport track T1, T2, T3 and/or horizontally.

Preferably, the cleaning apparatus 6 and/or the handling system 4B and/or the first handling device 6G comprises a fourth handover device 6K for transferring spectacle lenses 2 between the transfer device 6P and the holder 6N associated with the first cleaning chamber 6A.

The fourth handover device 6K is preferably identical in construction to the first, second and/or third handover device 6K.

The fourth handover device 6K is preferably pivotable, in particular between a first position in which the fourth handover device 6K is preferably arranged below the holder 6Q, and a second position in which the fourth handover device 6K is preferably arranged above the opening 6L of the first cleaning chamber 6A and/or below the holder 6H associated with the first cleaning chamber 6A.

Preferably, the transfer device 6P is configured to remove a spectacle lens 2 from the transport system 11 and/or from a transport container 11D and then transfer the spectacle lens 2 to the fourth handover device 6K and deposit it in the handover device 6K. The handover device 6K is preferably configured to center the spectacle lens 2 and pivot into a position in which the holder 6H associated with the first cleaning chamber 6A can remove the spectacle lens 2 from the handover device 6K.

### First Coating Apparatus

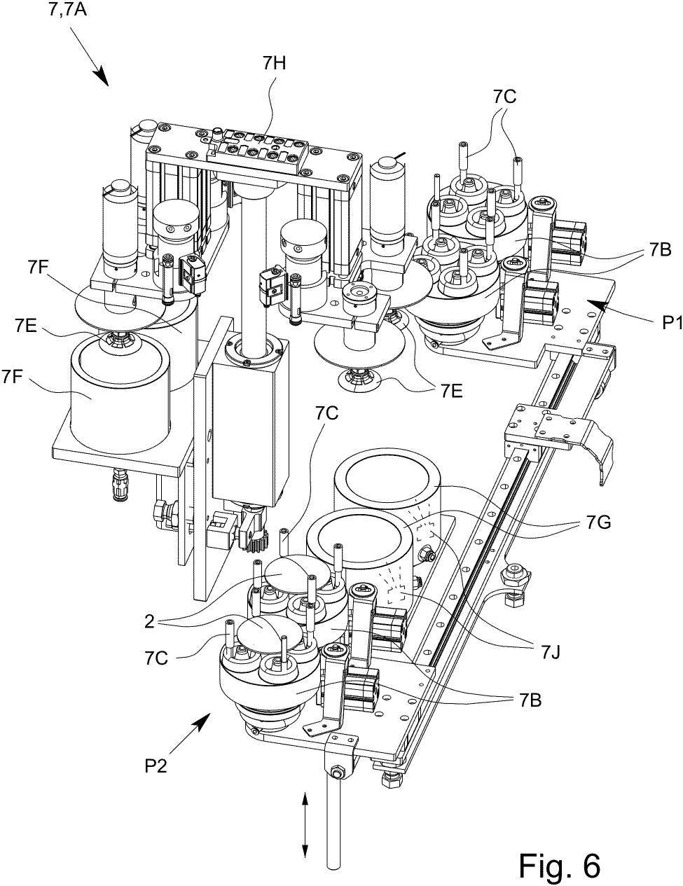

The first coating apparatus 7 is shown in particular in FIG. 6.

The first coating apparatus 7 is preferably arranged immediately downstream of the cleaning apparatus 6. In particular, the first coating apparatus 7 is designed for directly and/or automatically taking over spectacle lenses 2 from the cleaning apparatus 6 and/or transfer device 6M.

The first coating apparatus 7 is preferably configured for applying the hard layer 5A to a spectacle lens 2 or a flat side 2A, 2B of a spectacle lens 2.

The first coating apparatus 7 preferably comprises at least one coating chamber 7F. The coating chamber 7F is preferably configured for applying the hard layer 5A to the spectacle lens 2 or to a flat side 2A, 2B of the spectacle lens 2.

Preferably, a liquid coating material is applied, in particular sprayed, in the coating chamber 7F onto the flat side 2A, 2B of the spectacle lens 2 to be coated, while the spectacle lens 2 is rotated about an axis of rotation which is preferably at least substantially perpendicular to the flat side 2A, 2B. As a result of this, due to the centrifugal force, the coating material is distributed on the flat side 2A, 2B and excess coating material is spun away to the outside so that a hard layer 5A with a thickness as uniform as possible is formed. This process is also known as “spin coating”.

Preferably, the first coating apparatus 7 comprises at least one curing chamber 7G for curing the hard layer 5A.

The curing chamber 7G preferably comprises a curing device 7J - only schematically indicated in FIG. 6. Preferably, the curing is performed by irradiating the spectacle lens 2 with electromagnetic radiation, in particular UV radiation, and/or the curing device 7J is a source of electromagnetic radiation, in particular a source of UV radiation.

The first coating apparatus 7 is preferably designed for coating and/or applying and/or curing the hard layer 5A in pairs. Particularly preferably, the first coating apparatus 7 has for this purpose at least two, preferably structurally identical, coating chambers 7F and/or at least two, preferably structurally identical, curing chambers 7G.

The coating installation 4 and/or the handling system 4B and/or the first coating apparatus 7 preferably comprises a handling device 7A, hereinafter referred to in particular as the second handling device 7A.

Preferably, the second handling device 7A comprises one or more holders for holding a respective spectacle lens 2. Preferably, the second handling device 7A comprises different types of holders.

Preferably, at least one holder is formed as a gripper 7B with which the spectacle lenses 2 can be held at their edge, in particular so that contact with or damage to the spectacle lens surfaces or flat sides 2A, 2B is avoided. In particular, the gripper 7B has a plurality of fingers 7C which are or can be placed against the edge 2C of the spectacle lens 2 to hold it. This is illustrated in particular in FIG. 6.

Preferably, the second handling device 7A has, in particular in addition to the gripper 7B, at least one holder, which is in the form of a suction cup 7E, with which the spectacle lenses 2 can preferably be held on one flat side 2A, 2B. This enables in particular the (full-surface) application of the coating 5 or of a layer 5A, 5B of the coating 5, in particular the hard layer 5A, to the other, free flat side 2A, 2B of the spectacle lens 2.

The first coating apparatus 7 and/or the second handling device 7A and/or the suction cup 7E is preferably designed for holding, in particular rotating holding, a spectacle lens 2 during the application of the hard layer 5A in a coating chamber 7F and/or during the curing of the hard layer 5A in a curing chamber 7G.

The suction cup 7E is preferably vertically and/or linearly movable.

Preferably, the spectacle lens 2 held on the suction cup 7E is moved vertically and/or from above into the coating chamber 7F or curing chamber 7G and/or the hard layer 5A is applied or cured there - in particular from below. After the hard layer 5A has been applied or cured, the spectacle lens 2 or the suction cup 7E is preferably moved out of the coating chamber 7F or curing chamber 7G again.

Preferably, each coating chamber 7F and/or each curing chamber 7G has associated therewith a suction cup 7E for holding a spectacle lens 2 in the coating chamber 7F and/or curing chamber 7G during the application and/or curing of the hard layer 5A. Particularly preferably, the first coating apparatus 7 and/or second handling device 7A comprises four suction cups 7E or two pairs of suction cups 7E.

Preferably, the suction cups 7E and/or the pairs of suction cups 7E are movable independently of each other.

The suction cups 7E and/or pairs of suction cups 7E are preferably pivotable - in particular individually and/or in pairs - from the coating chamber(s) 7F to the curing chamber(s) 7G and vice versa.

The suction cups 7E are preferably arranged on a swivel unit 7H. The swivel unit 7H is preferably designed to swivel the suction cups 7E from the coating chamber(s) 7F to the curing chamber(s) 7G and vice versa.

Preferably, the coating chambers 7F are arranged on one side of the swivel unit 7H. Preferably, the curing chambers 7G are arranged on the side of the swivel unit 7H opposite the coating chambers 7F. By means of the swivel unit 7H, the suction cups 7E are pivotable, preferably by 180°, so that the suction cups 7E and/or pairs of suction cups 7E are pivotable from a position above the coating chambers 7F to a position above the curing chambers 7G and vice versa.

Preferably, the first coating apparatus 7 and/or second handling device 7A comprises a plurality of grippers 7B, particularly preferably at least four grippers 7B or at least two pairs P1, P2 of grippers 7B.

Preferably, the grippers 7B of the first pair P1 are or the first pair P1 of grippers 7B is designed for taking over spectacle lenses 2 from the cleaning apparatus 6 and/or the transfer device 6M and/or for handing over spectacle lenses 2 to the suction cups 7E. The grippers 7B of the second pair P2 or the second pair P2 of grippers 7B are/is preferably designed for taking over spectacle lenses 2 from the suction cups 7E and/or for handing over spectacle lenses 2 to the intermediate storage apparatus 8 and/or handling device 8A, which will be described later.

Preferably, the grippers 7B and/or pairs P1, P2 are movable, in particular linearly and/or along a linear guide or rail. The grippers 7B and/or pairs P1, P2 are preferably arranged on a common rail.

The first pair P1 and/or its grippers 7B is/are preferably movable and/or traversable (along the rail) between a first position, in which spectacle lenses 2 can be or are taken over from the cleaning apparatus 6 and/or the first handling device 6G, and a second position, in which the pair P1 and/or the grippers 7B is/are arranged below suction cups 7E and/or in which the suction cups 7E can each take over a spectacle lens 2 from the grippers 7B.

The second pair P2 and/or its grippers 7B is/are preferably movable between a first position, in which the pair P1 and/or the grippers 7B is/are arranged below suction cups 7E and/or in which spectacle lenses 2 can be or are taken over from the cleaning apparatus 6 and/or the first handling device 6G, and a second position, in which the spectacle lenses 2 can be or are handed over to the intermediate storage apparatus 8 and/or the handling device 8A.

Preferably, the curing chamber(s) 7G is/are vertically movable. The curing chamber(s) 7G are preferably arranged or arrangeable below the grippers 7B. On the one hand, this has the advantage of a space-saving structure. On the other hand, this simplifies the handling and/or the construction of the second handling device 7A. In this way, it is sufficient that the grippers 7B are only movable horizontally and the suction cups 7E are only pivotable by means of the swivel unit 7H and movable vertically and/or linearly.

To transfer spectacle lenses 2 between the grippers 7B and suction cups 7E, the curing chambers 7G are preferably moved to a position vertically below the grippers 7B and/or the plane in which the grippers 7B are arranged. Then, the grippers 7B can be moved below the suction cups 7E and/or between the suction cups 7E and the curing chambers 7G and spectacle lenses can be transferred / handed over between the grippers 7B and suction cups 7E. The grippers 7B are then moved away again, and the curing chambers 7G can be moved vertically upwards and/or towards the suction cups 7E so that the suction cups 7E can move spectacle lenses 2 into the curing chambers 7G.

Preferably, the sequence in the first coating apparatus 7 is as follows:

First, the first pair P1 of grippers 7B each take over a spectacle lens 2 from the cleaning apparatus 6 and/or the transfer device 6M. The spectacle lenses 2 are then positioned by means of the grippers 7B so that they can be taken over by the suction cups 7E from the grippers 7B.

The suction cups 7E each remove a spectacle lens 2 from one of the grippers 7B and then move the spectacle lenses 2 into the coating chambers 7F, in particular simultaneously or at the same time.

After the hard layer 5A has been applied in the coating chambers 7F, the spectacle lenses 2 are moved out of the coating chambers 7F again with the suction cups 7E. Then, the swivel unit 7H is swiveled 180° so that the suction cups 7E with the spectacle lenses 2 are positioned above the curing chambers 7G. The spectacle lenses 2 are then moved with the suction cups 7E into the curing chambers 7G, and the hard layer 5A is cured there.

Subsequently, the spectacle lenses 2 are moved out of the curing chambers 7G with the suction cups 7E and the suction cups 7E are swiveled by 180° again by means of the swivel unit 7H.

Then, the spectacle lenses 2 are handed over from the suction cups 7E to the second pair P2 of grippers 7B and are moved to and handed over to the intermediate storage apparatus 8 and/or handling device 8A by the second pair P2 of grippers 7B.

While a pair of spectacle lenses 2 are being coated with the hard layer 5A in the coating chamber 7F, another pair of spectacle lenses 2 is preferably being cured in the curing chamber 7G. This is conducive to an efficient and/or time-saving sequence.

While preferably a pairwise loading of the coating chambers 7F and/or curing chambers 7G and/or a pairwise processing of the spectacle lenses 2 takes place in the coating chambers 7F and/or curing chambers 7G, the coating chambers 7F and/or curing chambers 7G are preferably independent of each other. In particular, the coating chambers 7F and/or curing chambers 7G are movable and/or controllable so that each coating chamber 7F and/or curing chamber 7G is loadable with a (single) spectacle lens 2 and/or a (single) spectacle lens 2 is processable in each chamber 7F, 7G independently of the other chambers 7F, 7G.

### Intermediate Storage Apparatus

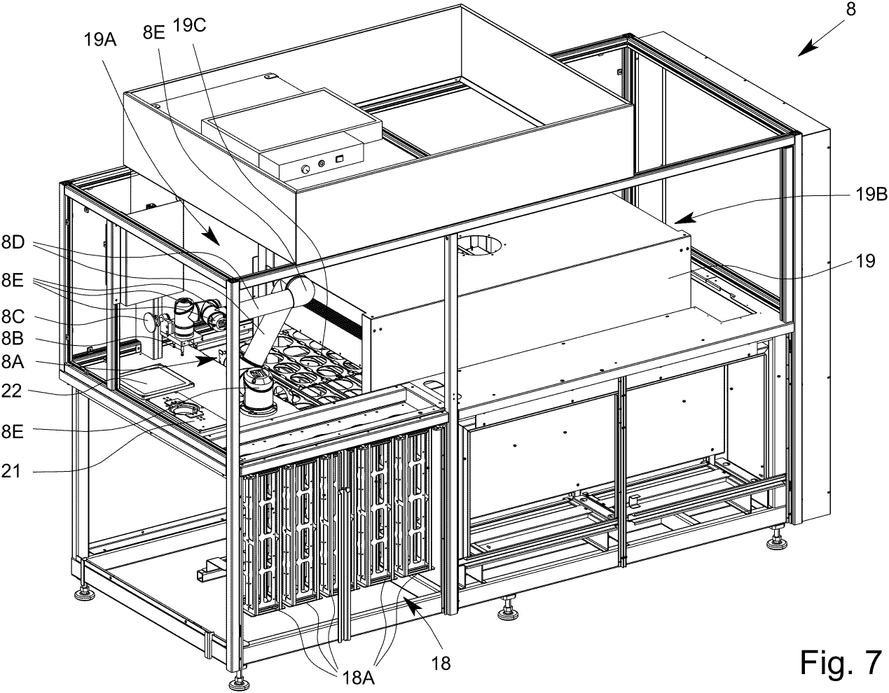

The intermediate storage apparatus 8 is in particular shown in FIG. 7.

In particular, the intermediate storage apparatus 8 is configured for intermediate storage of spectacle lenses 2 and/or drying and/or curing of the hard layer 5A.

After curing of the hard layer 5A in the curing chamber 7G of the first coating apparatus 7, the hard layer 5A is preferably not yet completely cured, but only cured to such an extent that it no longer changes its shape and the spectacle lens 2 can already be passed on for further processing and/or treatment. The complete drying and/or complete curing of the hard layer 5A preferably takes place in the intermediate storage apparatus 8.

The intermediate storage apparatus 8 is preferably arranged immediately downstream of the first coating apparatus 7. In particular, the intermediate storage apparatus 8 is designed for the direct and/or automated takeover of spectacle lenses 2 from the first coating apparatus 7.

The intermediate storage apparatus 8 is preferably configured to clamp the spectacle lenses 2 in clamping rings 17 and for intermediate storage of the spectacle lenses 2 clamped in the clamping rings 17.

Preferably, the intermediate storage apparatus 8 and/or the handling system 4B comprises a magazine 18 for the clamping rings 17.

### Clamping Ring

A clamping ring 17 according to the proposal is in particular shown in FIGS. 8 and 9.

Preferably, the spectacle lenses 2 are each inserted into a clamping ring 17 in the coating installation 4 and/or second coating apparatus 9 and/or held in a clamping ring 17 during coating in the second coating apparatus 9.

Preferably, it is provided that the spectacle lenses 2 are only temporarily held in clamping rings 17 during coating in the coating installation 4. In other words, some operations are preferably carried out in the coating installation 4 without the spectacle lenses 2 being held in clamping rings 17.

Preferably, the spectacle lenses 2 are handled in the cleaning apparatus 6 and/or first coating apparatus 7 without clamping rings 17 and/or are inserted into clamping rings 17 in the intermediate storage apparatus 8 and/or are held in clamping rings 17 in the intermediate storage apparatus 8 and/or second coating apparatus 9.

Preferably, the clamping ring 17 is configured for (subsequently) holding the spectacle lens 2 on the edge side and/or for holding the spectacle lens 2 on the edge 2C. In FIG. 9, it is schematically shown how a spectacle lens 2 is held in the clamping ring 17 with arms 17A.

Preferably, the clamping ring 17 comprises a plurality of flexible arms 17A for edge clamping the spectacle lens 2. The arms 17A and/or the edge clamping in particular ensure that the hard layer 5A or other layer applied to the first and/or second flat side 2A, 2B in the first coating apparatus 7 is not damaged and/or that a complete and/or uniform coating of the first and/or second flat side 2A, 2B can take place in the second coating apparatus 9.

In particular, the arms 17A are designed to be tensionable against the spectacle lens 2 and/or resilient and/or elastic. Preferably, the arms 17A are formed as leaf springs and/or the arms 17A are made of metal, in particular spring steel. However, other implementations are also possible, for example with spring-biased pivot arms or contact elements.

The arms 17A are preferably curved, in particular at least substantially semicircular in shape.

Preferably, the clamping ring 17 comprises a frame 17B.

The frame 17B is preferably ring-like and/or at least substantially circular and/or annular in section.

The clamping ring 17 and/or frame 17B preferably has or forms an annular portion or flange 17D. The flange 17D is preferably annular and/or preferably extends radially and/or perpendicularly to the cylindrical portion 17C.

The frame 17D is preferably formed by the cylindrical portion 17C and the flange 17D.

Preferably, the arms 17A are attached, in particular with one end, to the frame 17B, in particular the cylindrical portion 17C. Preferably, the arms 17A project inwardly from an annulus, in particular the frame 17B and/or the cylindrical portion 17C.

The clamping ring 17 and/or frame 17B and/or flange 17D preferably comprises an orientation means 17E. The clamping ring 17 and/or orientation means 17E is preferably configured for oriented gripping or handling of the clamping ring 17 and/or oriented insertion of the clamping ring 17 into the magazine 18 and/or a carrier 20. The magazine 18 and the carrier 20 will be described in more detail later.

The orientation means 17E is preferably arranged on an outer side of the clamping ring 17.

In particular, the orientation means 17E comprises or is formed by one or more recesses.

In the illustrative example, the orientation means 17E is formed by recesses on the edge or outer side of the frame 17B and/or flange 17D. In principle, however, other solutions are also possible, for example breakthroughs and/or holes in the frame 17B and/or flange 17D.

The orientation means 17E is preferably configured such that the clamping ring 17 can only be inserted into the magazine 18 in a single defined or predetermined orientation or rotational position, in particular defined by the orientation means 17E.

In particular, the orientation means 17E and/or the recesses are arranged asymmetrically on the clamping ring 17 and/or frame 17B and/or are distributed over the clamping ring 17 and/or frame 17B. Alternatively or additionally, the orientation means 17E may have an odd number of recesses. Preferably, the clamping ring 17 and/or the frame 17B has a rotationally asymmetric shape, which is generated in particular by the orientation means 17E.

In the illustrative example according to FIGS. 8 and 9, the orientation means 17E has an odd number of recesses, in particular three recesses, the recesses being distributed asymmetrically over the circumference of the clamping ring 17.

The various recesses may have different shapes, as shown in particular in FIGS. 8 and 9.

Preferably, the clamping ring 17 has a suction surface 17F for handling and/or holding the clamping ring 17 by means of a suction cup.

Preferably, the suction surface 17F is formed by the flange 17D and/or is ring-shaped.

The suction surface 17F preferably extends at least substantially parallel to a plane in which the lens 2 is clamped and/or clampable and/or held by the arm 17A.

The clamping ring 17 is preferably configured in such a way that a plurality of identical clamping rings 17 can be stacked vertically, in particular in such a way that arms 17A of adj acent clamping rings are spaced apart (in the stacking direction) and/or without arms 17A of adjacent clamping rings 17 touching each other. In particular, the frame 17B and/or flange 17D projects over the arms 17A radially inwards and/or perpendicularly to the plane in which the spectacle lens 2 is clamped and/or clampable and/or held by the arms 17A. In other words, the frame 17B and/or flange 17D covers the arms 17A radially, at least partially.

Alternatively or additionally, the frame 17B and/or cylindrical portion 17C is wider than the arms 17A in the direction of a cylinder axis defined by the cylindrical portion 17C, such that the frame 17B projects over the arms 17A in the direction of this cylinder axis.

The described design of the frame 17B in particular prevents the arms 17A of adjacent clamping rings 17 from contacting and/or interlocking with each other during stacking of clamping rings 17.

Preferably, the clamping ring 17 and/or frame 17B, in particular the cylindrical portion 17C, comprises at least one recess 17G. Preferably, the clamping ring 17 and/or frame 17B comprises a plurality of recesses 17G.

The recesses 17G are preferably arranged on the bottom side 17H of the clamping ring 17 and/or frame 17B. The bottom side 17H of the clamping ring 17 and/or frame 17B is in particular the side facing away from the flange 17D.

However, the recesses 17G may alternatively or additionally represent or form breakthroughs or holes in the frame 17B and/or cylindrical portion 17C.

In particular, the recesses 17G serve to allow cleaning liquid to drain off. It is preferably provided that a plurality of clamping rings 17 arranged or stacked one above the other in the magazine 18 are cleaned together. In this case, in particular, a (cylindrical) wall or column is formed by the frames 17B and/or the portions 17C of the clamping rings 17 stacked one on top of the other, the recesses 17G forming openings or holes in this wall or column, thereby allowing or improving a drainage of cleaning liquid. This can prevent residues of cleaning fluid from forming on the clamping rings 17, so that improved, in particular residue-free, cleaning and/or faster drying of the clamping rings 17 is achieved.

### Magazine

FIG. 7 also shows the magazine 18.

In particular, the magazine 18 is configured for (simultaneously) storing a plurality of clamping rings 17, preferably in a defined and/or the same orientation or rotational position, in particular in the form of one or more stacks of clamping rings 17.

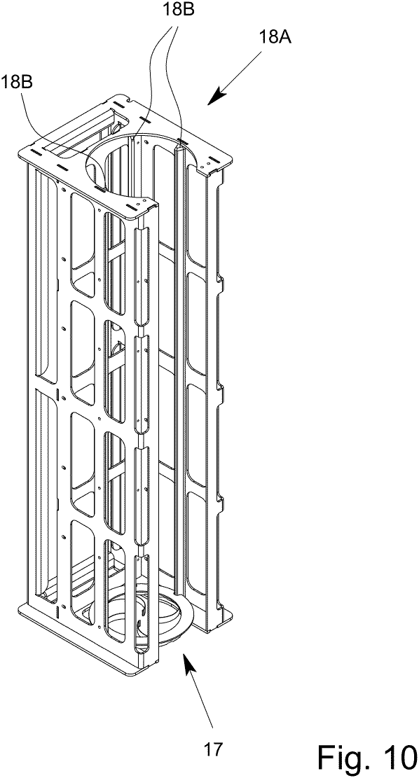

The magazine 18 preferably comprises or is formed by at least one magazine unit 18A. The magazine unit is shown in more detail in FIG. 10.

The magazine unit 18A or the magazine unit 18A can preferably be removed from the magazine 18 together with clamping rings 17 arranged therein. In particular, this allows a plurality of clamping rings 17 to be fed to a cleaning device and/or cleaned simultaneously. This is conducive to an automated and/or efficient process.

The magazine 18 and/or the magazine unit 18A is preferably columnar in shape.

Preferably, the magazine 18 comprises or is formed by several magazine units 18A of identical construction. Through this, a discharge or removal of magazine units 18A and/or clamping rings 17 from the coating installation 4 and/or intermediate storage apparatus 8 can take place without delays in the operating sequence of the coating installation 4 and/or without stopping the coating installation 4. In particular, this allows the coating installation 4 to be operated continuously and/or the “downtime”, i.e. the time during which the coating installation 4 is stopped or paused and/or during which no spectacle lenses 2 are coated in the coating installation 4, to be reduced or minimized or even completely avoided.

The magazine 18 preferably comprises an orientation means 18B. The orientation means 18B preferably corresponds to the orientation means 17E of the clamping rings 17 and/or is complementary to the orientation means 17E of the clamping rings 17.

By means of the orientation means 18B, the magazine 18 and/or the magazine unit 18A is preferably configured such that the clamping rings 17 can only be stored in the magazine 18 and/or the magazine unit 18A in a predetermined orientation or rotational position.

The orientation means 18B preferably comprises or is formed by one or more struts, projections or the like.

The orientation means 18B is preferably configured to engage the orientation means 17E and/or the recesses of the clamping rings 17 and/or has a shape complementary to the orientation means 17E and/or the recesses.

Preferably, several clamping rings 17 can be stacked or stored stacked in the magazine 18 and/or the magazine unit 18A in the same orientation or rotational position. In particular, the clamping rings 17 are arrangeable in the magazine 18 and/or the magazine unit 18A in such a way that a clamping ring 17 rests or abuts with the bottom side 17H of the frame 17B on or against the flange 17D of the clamping ring 17 arranged thereunder.

Preferably, a plurality of clamping rings 17, in particular more than 20, preferably more than 50, more preferably more than 100 clamping rings 17, can be stored or arranged in the magazine 18.

Preferably, the magazine 18 and/or the magazine unit 18A extends at least substantially vertically and/or the magazine 18 is configured for storing clamping rings 17 stacked vertically one above the other, in particular aligned in the same orientation or rotational position.

The stackability of the clamping rings 17 in the magazine 18 and/or the magazine unit 18A and/or the columnar design of the magazine 18 and/or the magazine unit 18A in particular enables a space-saving storage of the clamping rings 17.

Furthermore, stacking the clamping rings 17 in the same orientation facilitates or enables automated handling of the clamping rings 17.

### Heating Device

Preferably, the coating installation 4 and/or intermediate storage apparatus 8 comprises a heating device 19.

The heating device 19 is preferably designed to heat the spectacle lenses 2, in particular so that the heating dries and/or cures the previously applied hard coating 5A.

The heating device 19 is preferably designed as a kiln/oven. The heating device 19 or the kiln/oven is in particular designed to generate a temperature of more than 40° C., in particular more than 50° C., and/or less than 100° C., in particular less than 80° C., and/or to heat the spectacle lenses 2 to this temperature.

The heating device 19 is preferably configured to heat the spectacle lenses in a continuous process.

A continuous process in the sense of the present invention is in particular a process which runs continuously and/or without interruptions. With reference to the heating device 19, this means in particular that spectacle lenses 2 are heated in the heating device 19 continuously and/or without interruptions during operation of the heating device 19. In particular, further spectacle lenses 2 can be fed to the heating device 19 and/or spectacle lenses 2 can be removed from the heating device 19 while other spectacle lenses 2 are still in the heating device 19 and/or are being heated.

In particular, a continuous process contrasts with a process in which a certain number of spectacle lenses 2 are each fed simultaneously or in groups to the heating device 19, heated in the heating device and then removed again from the heating device 19 before the next group of spectacle lenses 2 is fed to the heating device 19. In such a discontinuous process, dead times occur in each case between the removal of a group of spectacle lenses 2 and the feeding of the next group of spectacle lenses 2 in the heating device 19, during which no spectacle lenses 2 are arranged or heated in the heating device 19.

The heating device 19 preferably has an inlet 19A and an outlet 19B. The inlet 19A is preferably formed separately from the outlet 19B. In particular, the inlet 19A and the outlet 19B are arranged on opposite sides of the heating device 19. This is shown in particular in FIG. 1.

The inlet 19A is preferably arranged near the magazine 18 and/or on a side of the heating device 19 facing the magazine 18. The outlet 19B is preferably arranged on a side of the heating device 19 and/or intermediate storage apparatus 8 opposite the inlet 19A and/or facing the second coating apparatus 9.

The coating installation 4 and/or second coating apparatus 9 and/or heating device 19 preferably comprises a transport device 19C. The transport device 19C is preferably configured for transporting spectacle lenses 2 through the intermediate storage apparatus 8 and/or heating device 19. The transport device 19C is preferably configured for transporting spectacle lenses 2 from the inlet 19A to the outlet 19B.

The time that the spectacle lenses 2 spend in the heating device 19 and/or in which the spectacle lenses 2 are transported from the inlet 19A to the outlet 19B is preferably more than 10 minutes, in particular more than 20 minutes, and/or less than 50 minutes, in particular less than 40 minutes, particularly preferably about 30 minutes.

The transport device 19C preferably has a transport direction R4. In particular, the transport direction R4 is from the inlet 19A to the outlet 19B.

The transport device 19C is preferably configured for the continuous transport of spectacle lenses 2.

The heating device 19 is preferably adapted to heat the spectacle lenses 2 during transport by the transport device 19C.

The transport device 19C is preferably designed to receive and/or transport spectacle lenses 2 held in clamping rings 17. Preferably, the transport device 19C comprises or is formed by a preferably endless conveyor belt or the like.

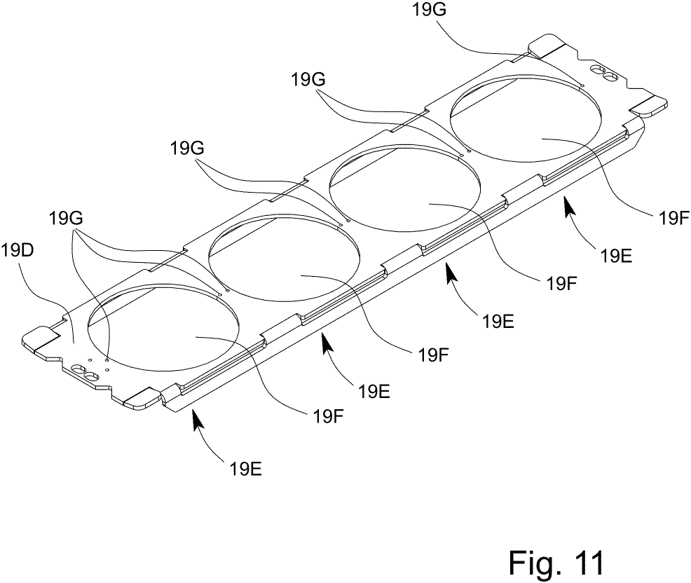

Preferably, the transport device 19C comprises a plurality of holders or strips 19D. In FIG. 11, one strip 19D of the transport device 19C is shown in more detail by way of example.

Preferably, the strips 19D are arranged directly adjacent to each other and/or transversely to the transport direction R4. Preferably, in each strip 19D several, for example two, four, six or eight, spectacle lenses 2 can be arranged adjacent to each other and/or transversely to the transport direction R4.

The strip 19D preferably has a plurality of storage locations 19E, each for receiving a spectacle lens 2 or a clamping ring 17 with a spectacle lens 2 held therein. The storage locations 19E are preferably arranged in a row. In principle, however, other arrangements are also possible, for example the arrangement of the storage locations in a rectangle or on the points of a grid or the like. Accordingly, the holder can also be designed other than in the form of a strip.

The storage location 19E preferably has a receptacle 19F in which the clamping ring 17 and/or frame 17B can be arranged. The receptacle 19F is preferably dimensioned such that the clamping ring 17, which has been inserted into the receptacle 19F, is inserted with the cylindrical portion 17C into the receptacle 19F and rests with the frame 17B on the strip 19D. Preferably, the receptacle 19F is at least substantially circular.

Furthermore, the storage location 19E preferably comprises one or more engagement elements 19G for engaging the orientation means 17E of the clamping ring 17. This allows the clamping rings 17 to be arranged (only) in a defined rotational position or orientation in the storage location 19E. Preferably, the engagement elements 19G are designed as protrusions on the strip 19D. Preferably, the engagement elements 19G define a position or rotational orientation of the clamping ring 17 in the storage location 19E.

The strips 19D are preferably connected to each other in the transport direction R4, so that together they form a conveyor belt and/or a continuous or endless chain, and/or are arranged side by side on a conveyor belt.

### Third Handling Device

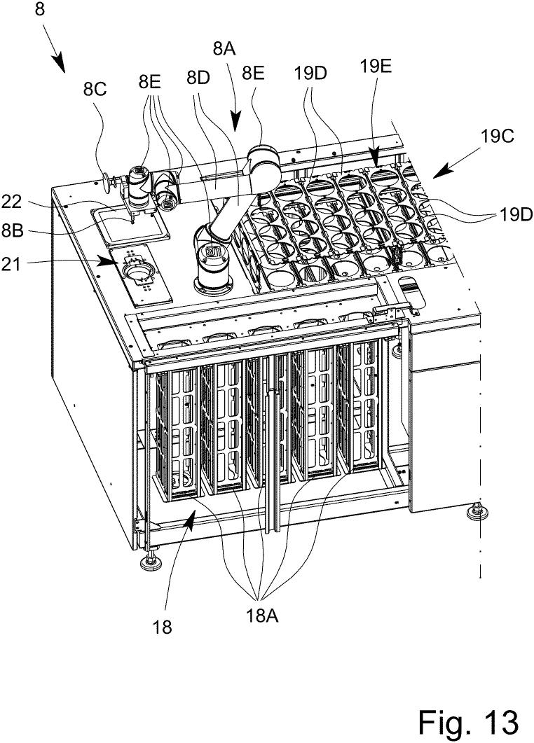

The intermediate storage apparatus 8 preferably comprises a handling device 8A, hereinafter referred to in particular as the third handling device 8A. The third handling device 8A is shown in particular in FIG. 13.

The third handling device 8A is preferably configured for (directly) taking over spectacle lenses 2 from the first coating apparatus 7 and/or the second handling device 7A.

Preferably, the third handling device 8A is designed for handling spectacle lenses 2 and/or clamping rings 17. Particularly preferably, the third handling device 8A comprises a plurality of holding devices 8B, 8C.

Preferably, the holding device 8B is designed for holding a spectacle lens 2. Preferably, the holding device 8B is designed as a gripper for holding a spectacle lens 2 on the edge side and/or for holding a spectacle lens 2 at its edge 2C.

Preferably, the holding device 8C is designed to hold a clamping ring 17. In particular, the holding device 8C is designed as a suction cup.

The third handling device 8A preferably comprises or is formed by a robot.

Preferably, the robot comprises a plurality of, in particular at least two, robot arms 8D and/or a plurality of axes of motion or degrees of freedom.

Preferably, the robot comprises a plurality of joints 8E. In particular, the robot has more than four and/or less than eight, particularly preferably six, joints 8E.

Preferably, the joints are each designed as rotating joints 8E. The joints are preferably each rotatable by 360°.

### Handling in Intermediate Storage Apparatus

The coating installation 4 and/or intermediate storage apparatus 8 and/or the handling system 4B preferably has a clamping device 21 for clamping spectacle lenses 2 in the clamping rings 17 and/or for - in particular automated and/or mechanical - insertion of spectacle lenses 2 into the clamping rings 17, particularly preferably with a defined orientation or rotational position. The clamping device 21 is preferably designed to receive, open and/or close a clamping ring 17.

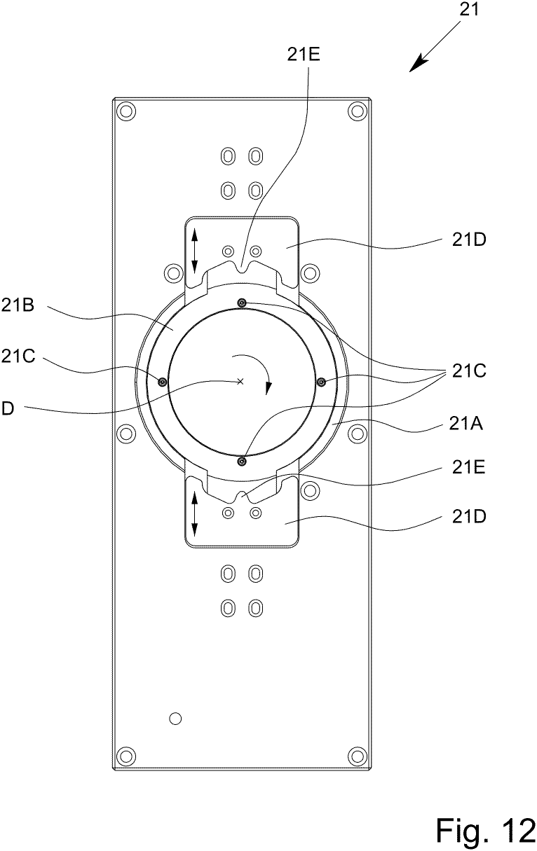

The clamping device 21 is shown in particular in FIG. 12.

By an opening of the clamping ring 17, it is understood in particular the moving of the arms 17A outwards and/or towards the frame 17B, so that a free space in the centre of the clamping ring 17 and/or between the arms 17A is increased and a spectacle lens 2 can be inserted into the clamping rings 17 and/or between the arms 17A.

By a closing of the clamping ring 17, it is understood in particular to allow the arms 17A to return to their original position so that they bear against the edge 2C of the spectacle lens 2 and hold the spectacle lens 2 in the clamping ring 17.

Preferably, the clamping device 21 comprises a receptacle 21A for receiving a clamping ring 17. Preferably, a clamping ring 17 can be inserted into the receptacle 21A and/or arranged in the receptacle 21A. The receptacle 21A preferably has or is formed by a bearing surface, in particular of ring-like design, for the flange 17D of the clamping ring 17 or frame 17B.

The clamping device 21 preferably comprises an opening device 21B for opening the clamping ring 17. The opening device 21B is preferably rotatable about an axis of rotation D. The axis of rotation D preferably extends transversely, in particular perpendicularly, to the plane in which the clamping ring 17 is arranged in the receptacle 21A.

The opening device 21B preferably comprises a plurality of pins 21C. The pins 21C are preferably each configured to move one of the arms 17A of the clamping ring 17, so as to open the clamping ring 17. The opening device 21B and/or the pins 21C is/are preferably arranged such that the pins 21C engage the arms 17A when the clamping ring 17 is inserted into the clamping device 21 and/or receptacle 21A and/or the receptacle 21A is rotated (relative to the clamping ring 17).

Preferably, the number of pins 21C corresponds to the number of arms 17A of the clamping ring 17. In particular, the clamping device 21 or opening device 21B comprises four pins 21C.

The pins 21C are preferably arranged on a circular ring, in particular each at 90° to the other. The pins 21C are preferably arranged in such a way that, when the clamping ring 17 has been inserted into the receptacle 21A, they are located near the end of the arms 17A fixed to the frame 17B.

The clamping device 21 preferably comprises one or more fixing means 21D for fixing the clamping ring 17 in the clamping device 21 and/or receptacle 21A. The fixing means 21D is/are preferably formed as jaws. Preferably, the fixing means 21D is/are arranged above the receptacle 21A, so that the clamping ring 17 and/or frame 17B can be clamped and/or positively fixed between the receptacle 21A and the fixing means 21D.

Preferably, the clamping device 21 and/or the fixing means 21D has one or more engagement elements 21E for engaging the clamping ring 17 and/or its orientation means 17E and/or the recesses of the orientation means 17E. Preferably, the fixing means 21D here comprises an engagement element 21E. Preferably, the engagement element 21E is a portion of the fixing means 21D.

Preferably, a clamping ring 17 can be arranged in the clamping device 21 and/or the receptacle 21A only in a specific or defined rotational position, in particular defined by the engagement elements 21E.

Preferably, the fixing means 21D and/or engagement elements 21E are arranged on radially opposite sides of the receptacle 21A.

Preferably, the engagement elements 21E are complementary to the orientation means 17E of the clamping ring 17.

The fixing means 21D and/or engagement elements 21E are preferably movable radially with respect to the axis of rotation D and/or the receptacle 21A.

The fixing means 21D and/or engagement elements 21E are preferably adapted to hold the clamping ring 17 and/or frame 17B in a fixed position, while the opening means 21B and/or pins 21C are used to open the clamping ring 17 and/or move the arms 17A.

In order to insert the clamping ring 17 into the clamping device 21 and/or receptacle 21A, the fixing means 21D are preferably moved radially outwards and/or away from each other so that the receptacle 21A is cleared and the clamping ring 17 can be inserted. This position of the fixing means 21D is shown in particular in FIG. 12.

The clamping ring 17 is preferably inserted into the clamping device 21 in a defined orientation or rotational position, so that the orientation means 17E and/or its recesses are arranged such that the engagement elements 21E can engage in the recesses and/or the orientation means 17E.

After the clamping ring 17 has been inserted into the clamping device 21 and/or receptacle 21A, the fixing means 21D are preferably moved, in particular radially inwards and/or towards each other and/or the clamping ring 17, so that the engagement elements 21E engage in the recesses and/or orientation means 17E of the clamping ring 17 and the fixing means 21D at least partially cover the frame 17B and/or flange 17D and thus fix the frame 17B in a fixed position in the receptacle 21A and/or clamping device 21.

Then, preferably, the opening device 21B is rotated about the axis of rotation D so that the pins 21C move along the arms 17A and thus move them radially outwards, so that a free area between the arms 17A is increased in the center of the clamping ring 17, so that a spectacle lens 2 can be arranged between the arms 17A and/or inserted into the clamping ring 17.

After the spectacle lens 2 has been positioned accordingly, the opening device 21B is preferably rotated in the opposite direction about the axis of rotation D so that the pins 21C move back to the previous position. Here, the arms 17A move back towards the center of the clamping ring 17 due to their elasticity, so that they finally abut against the spectacle lens 2 or its edge 2C and thus hold or clamp the spectacle lens 2.

After this insertion and/or clamping of the spectacle lens 2 in the clamping ring 17, the fixing means 21D are moved back outwards and/or back to the initial position before insertion of the clamping ring 17 in the receptacle 21A, so that the engagement elements 21E no longer engage in the orientation means 17E and/or the recesses and/or the fixing means 21D no longer cover the clamping ring 17 and/or frame 17B and the clamping ring 17 is released again.

Subsequently, the clamping ring 17 with the spectacle lens 2 held or clamped therein can be removed again from the clamping device 21 or receptacle 21A.

The intermediate storage apparatus 8 and/or clamping device 21 preferably has a measuring device 22 for measuring or determining the rotational position or orientation of a spectacle lens 2 before the spectacle lens 2 is inserted into the clamping ring 17. By means of the measuring device 22, it is preferably possible to check or verify whether the spectacle lens 2 is already correctly oriented or still has to be moved into a different orientation or rotational position before insertion into the clamping ring 17.

Preferably, the measuring device 22 has or is formed by a camera. However, in principle any, in particular tactile and/or optical, measuring methods for determining the orientation of the spectacle lens 2 are possible.

The third handling device 8A is preferably configured to remove clamping rings 17 from the magazine 18 and/or to insert them into the clamping device 21. Alternatively or additionally, the third handling device 8A is preferably configured to take spectacle lenses 2 from the first coating apparatus 7 and/or the second handling device 7A and/or to insert a spectacle lens into a clamping ring 17 that is arranged in the clamping device 21 and opened.

Preferably, the third handling device 8A is arranged between the magazine 18, the clamping device 21, the measuring device 22 and/or the heating device 19 and/or transport device 19C. This can be seen in particular from FIG. 13.

Preferably, the clamping device 21 and the third handling device 8A are coordinated with each other such that a clamping ring 17 is first removed from the magazine 18 and/or a magazine unit 18A by the third handling device 8A and inserted into the clamping device 21, then the clamping ring 17 is opened by the clamping device 21 and a spectacle lens 2 is inserted into the opened clamping ring 17 by the third handling device 8A, and after the spectacle lens 2 has been inserted into the clamping ring 17, the clamping device 21 closes the clamping ring 17.

Before inserting the spectacle lens 2, the third handling device 8A preferably holds the spectacle lens 2 in the measuring device 22 or transfers the spectacle lens 2 to the measuring device 22 and the measuring device 22 measures the spectacle lens 2 to check or control the orientation or rotational position of the spectacle lens 2. The measurement results from the measuring device 22 are processed and passed on to the third handling device 8A, so that the third handling device 8A corrects the orientation or rotational position of the spectacle lens 2 if necessary before insertion into the clamping ring 17, in particular by rotating the holding device 8B with the spectacle lens 2 until the spectacle lens 2 is oriented in the desired orientation or rotational position.

After inserting a spectacle lens 2 into the clamping ring 17, the third handling device 8A preferably removes the clamping ring 17 with the spectacle lens 2 inserted therein from the clamping device 21 and transfers the clamping ring 17 to the heating device 19 and/or transport device 19C, in particular by inserting the clamping ring 17 into a storage location 19E of the transport device 19C.

### Second Coating Apparatus

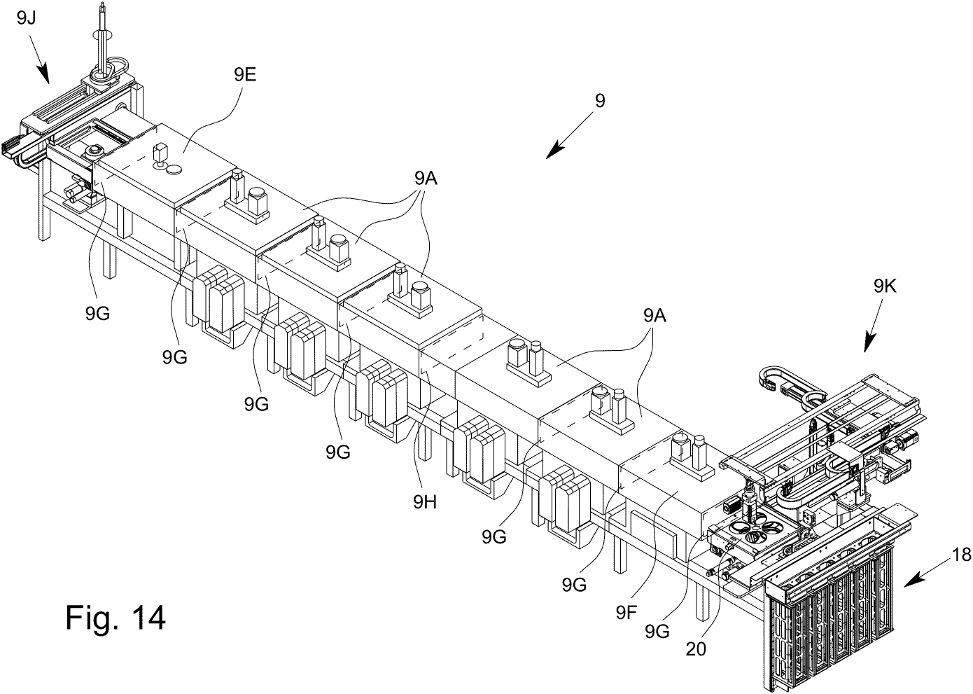

The second coating apparatus 9 is preferably arranged immediately downstream of the intermediate storage apparatus 8. In particular, the second coating apparatus 9 is designed for directly and/or automatically taking over spectacle lenses 2 from the intermediate storage apparatus 8. The second coating apparatus 9 is shown in particular in FIG. 14.

The second coating apparatus 9 preferably comprises one or preferably a plurality of coating chambers 9A, in particular arranged in series. In principle, however, the second coating apparatus 9 may alternatively or additionally comprise a plurality of coating chambers 9A arranged in parallel. Thus, any combination of parallel and serially arranged coating chambers 9A is possible.

The coating chambers 9A are preferably directly adjacent and/or directly connected to each other. Preferably, the coating chambers 9A form a continuous vacuum system. Preferably, the coating chambers 9A are separated or separable from each other. In particular, relatively small coating chambers 9A separate from each other can be realized in this way, so that the pumping times required to generate the vacuum and thus the processing time of the spectacle lenses 2 in the second coating apparatus 9 is reduced or minimized.

Preferably, the coating chambers 9A and/or the second coating apparatus 9 comprises a common casing/cladding and/or a common protective housing. In particular, the second coating apparatus 9 comprises or forms a clean room. In this way, contamination of the spectacle lenses 2, for example by dust, can be avoided and thus a high quality of the spectacle lenses 2 and/or coating 5 can be ensured.

The second coating apparatus 9 is preferably configured to apply one or more functional layers 5B of the permanent coating 5 to the spectacle lenses 2. The application of the layers or functional layers 5B is preferably carried out in a vacuum.

Preferably, the second coating apparatus 9 is configured to apply different functional layers 5B in the respective coating chambers 9A. In particular, the second coating apparatus 9 is configured to apply in the coating chambers 9A different layers 5B of an antireflection coating, at least one hydrophobic functional layer 5B and/or at least one oleophobic functional layer 5B.

Preferably, the second coating apparatus 9 and/or the coating chambers 9A is/are designed for coating spectacle lenses 2 by means of cathode sputtering or sputtering, in particular magnetron sputtering. Preferably, the coating chambers 9A are configured as described in WO 2018/108432 A1 and/or the coating is carried out as described in WO 2018/108432 A1.

The coating chambers 9A preferably each comprise one or more cathodes 9B with coating material for coating the spectacle lenses 2 and/or for generating the coating 5. Preferably, the cathodes 9B are at least substantially cylindrical. Preferably, the cathodes 9B are arranged at least substantially horizontally in the coating chambers 9A.

Preferably, the second coating apparatus 9 comprises at least one, preferably a plurality of, carriers 20. The carrier 20 can be seen in particular in FIG. 14.

The carrier 20 is preferably configured to receive a plurality of spectacle lenses 2 and/or a plurality of clamping rings 17 with spectacle lenses 2 held therein. In the illustrative example, the carrier 20 is designed to receive spectacle lenses 2 and/or four clamping rings 17.

Preferably, the second coating apparatus 9 and/or the carrier 20 is adapted to rotatably hold the spectacle lenses 2 and/or clamping rings 17. Thus, while the spectacle lenses 2 and/or clamping rings 17 are held with the carrier 20 and/or by the carrier 20, the spectacle lenses 2 and/or clamping rings 17 are preferably rotated. This allows a more uniform coating of the spectacle lenses 2. The quality of the coating 5 is thereby increased.

The carrier 20 is preferably at least substantially flat and/or rectangular.

The carrier 20 and/or the lenses 2 is/are preferably arranged (in the coating chambers 9A and/or during coating) at least substantially horizontally and/or parallel to a plane in which the cathodes 9B are arranged.

The second coating apparatus 9 preferably comprises a drive and/or a rotational coupling - not shown in the figures - for coupling with the carrier 20 and for rotating the spectacle lenses 2 and/or clamping rings 17 in the carrier 20. The coupling with the carrier 20 is preferably carried out automatically.

Preferably, the carrier 20 is configured as a cover or lid for a or the respective coating chamber 9A. Optionally, the carrier 20 is designed to close or cover a coating chamber 9A, in particular an upper side of a coating chamber 9A, during coating or a coating process, optionally even in a gas-tight and/or vacuum-tight manner.

The carrier 20 preferably has a plurality of receptacles 20A for receiving a plurality of clamping rings 17. The clamping rings 17 are preferably each rotatable about their central axis in the receptacles 20A.

The carrier 20 optionally has a common cover or a plurality of separate covers for the receptacles 20A and/or lenses 2. The cover is preferably formed as a lid and/or plate-like. The cover is preferably arranged on a side of the carrier 20 facing away from the cathodes 9B and/or on an upper side of the carrier 20.

In particular, the cover can prevent or reduce coating material from reaching one or more walls of the respective coating chamber 9A, in particular the wall arranged on the side of the carrier 20 facing away from the cathodes 9B, and/or from reaching the flat side 2A, 2B of the spectacle lens 2 not intended to be coated.

Preferably, the cover is pivotable, so that for inserting and/or removing a spectacle lens 2 and/or clamping ring 17 with a spectacle lens 2, the receptacle 20A can be uncovered by pivoting the cover. Alternatively or additionally, the cover may be plate-like, and/or completely separable from the carrier 20 and/or replaceable.

Instead of or in addition to the cover, the coating chamber 9A may comprise, in particular on the side of the carrier 20 facing away from the cathodes 9B and/or on the upper side of the carrier 20, a casing/cladding which is removable or replaceable for cleaning.

Preferably, the second coating apparatus 9 comprises a transport device 9C for transporting the carriers 20 through the second coating apparatus 9 and/or the coating chambers 9A. Preferably, the transport device 9C is configured to automatically transport the carriers 20 from one coating chamber 9A to the next coating chamber 9A. Preferably, the transport device 9C is formed continuously and/or passes through the coating chambers 9A and/or the vacuum system.

The second coating apparatus 9 and/or transport device 9C preferably comprises a return transport device 9D for automated return transport of carriers 20 after passing through the second coating apparatus 9 and/or the coating chambers 9A. The return transport device 9D is preferably arranged parallel to the transport device 9C. Preferably, the return transport device 9D is arranged parallel to the transport device 9C, in particular above the coating chambers 9A and/or laterally adjacent to the coating chambers 9A. This is conducive to a space-saving structure.

The return transport device 9D is preferably configured to transport the carriers 20 in a vertical orientation. This is conducive to a space-saving structure.

The second coating apparatus 9 preferably comprises an inlet chamber 9E and/or an outlet chamber 9F. The inlet chamber 9E and/or the outlet chamber 9F preferably form a continuous vacuum system with the coating chambers 9A.

Preferably, the inlet chamber 9E is arranged upstream of the coating chambers 9A. The outlet chamber 9F is preferably arranged downstream of the coating chambers 9A.

The inlet chamber 9E and/or the outlet chamber 9F are preferably configured to generate a pre-vacuum. In this way, the effort required to generate and/or maintain the vacuum in the coating chambers 9A can be reduced or minimized.

Preferably, the outlet chamber 9F is configured for applying a functional layer 5B, in particular an oleophobic and/or hydrophobic functional layer 5B, to the spectacle lenses 2. The functional layer 5B is preferably applied in the outlet chamber 9F by vapor deposition and/or an evaporation process. For this purpose, preferably only a pre-vacuum or a lower vacuum than for applying functional layers 5B by sputtering in the coating chambers 9A is required. The inlet chamber 9E and/or outlet chamber 9F preferably do not have any cathodes 9B.

The inlet chamber 9E, the outlet chamber 9F and/or the coating chambers 9A preferably each comprise a closure 9G, in particular a gas-tight and/or vacuum-tight closure 9G. Preferably, the closure 9G is formed by a flap, door or the like and/or is pivotable for opening or closing.

Preferably, the coating chamber 9A immediately adjacent to the inlet chamber 9E comprises a closure 9G arranged on the side of the coating chamber 9A facing the inlet chamber 9E and/or between the inlet chamber 9E and the coating chamber 9A. Preferably, the inlet chamber 9E is separated or separable from the coating chamber 9A by means of the closure 9G. In particular, only or exactly one closure 9G is provided for separating the inlet chamber 9E from the coating chamber 9A and/or the inlet chamber 9E has no (further) closure on the side facing the coating chamber 9A. This is conducive to a simple and cost-effective structure.

In principle, however, the inlet chamber 9E may also comprise the closure 9G for separating the inlet chamber 9E from the coating chamber 9A adjacent thereto.

Preferably, as described for the inlet chamber 9E and the coating chamber 9A adjacent thereto, the outlet chamber 9F and the coating chamber 9A immediately adjacent thereto are also separated or separable from each other by only or exactly one closure 9G.

Preferably, the coating chamber 9A immediately adjacent to the outlet chamber 9F comprises a closure 9G arranged on the side of the coating chamber 9A facing the outlet chamber 9F and/or between the outlet chamber 9F and the coating chamber 9A. Preferably, the outlet chamber 9F is separated or separable from the coating chamber 9A by means of the closure 9G. In particular, only or exactly one closure 9G is provided for separating the outlet chamber 9F from the coating chamber 9A and/or the outlet chamber 9F has no (further) closure on the side facing the coating chamber 9A. This is conducive to a simple and cost-effective structure.

Preferably, at least some of the coating chambers 9A are also separated or separable from each other by only or exactly one closure 9G, as described.

In the illustrative example, the inlet chamber 9E, coating chambers 9A and the outlet chamber 9F are each separated or separable from each other by (exactly) one closure 9G, wherein an additional closure 9H is provided between two of the coating chambers 9A so that these two coating chambers 9A are separated or separable from each other by two closures 9G, 9H, namely one closure 9G and the additional closure 9H.

The additional closure 9H is preferably identical in construction to the closure 9G.

The additional closure 9H simplifes the manufacture, transportation and/or set-up and/or installation of the coating installation 4 and/or second coating apparatus 9.

The coating chambers 9A and/or their operating parameters can preferably be operated, controlled and/or feedback-controlled independently of one another. In particular, different pressures and/or vacuums and/or temperatures can be set independently of one another in the coating chambers 9A. Preferably, the coating chambers 9A can be equipped with different cathodes 9B, which differ in particular by the coating material. Preferably, different inert gases and/or reactive gases can also be used in the different coating chambers 9A to support a sputtering process and/or deposition process. In principle, it is also possible to use different inert gases and/or reactive gases in a coating chamber 9A for different coating processes and/or for the coating of different spectacle lenses.

In this way, the coating installation 4, in particular the type, number, configuration and/or sequence of the coating chambers 9A of the second coating apparatus 9 can be individually and flexibly adapted to customer requirements.

In particular, the coating chambers 9A may be formed as modules and/or the coating apparatus 9 may be of modular construction, in particular so that the modules and/or coating chambers 9A may be flexibly combined with one another. In this way, the coating installation 4 and/or coating apparatus 9 can be flexibly used and/or assembled and/or adapted to individual requirements and/or customer wishes.

The coating installation 4 and/or the handling system 4B and/or the second coating apparatus 9 preferably comprises a handling device 9J, hereinafter referred to in particular as the fourth handling device 9J.

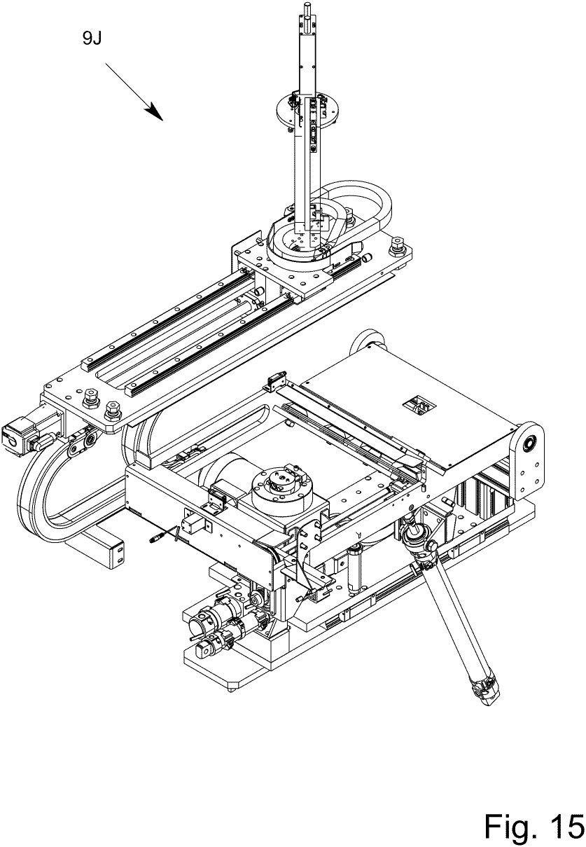

The fourth handling device 9J is in particular shown in FIG. 15.

The fourth handling device 9J is preferably arranged upstream of the inlet chamber 9E and/or the coating chambers 9A.

The fourth handling device 9J is preferably designed for the, in particular automated, takeover of spectacle lenses 2 from the heating device 19 and/or transport device 19C and/or for the removal of spectacle lenses 2 from the heating device 19 and/or transport device 19C.

Preferably, the fourth handling device 9J is adapted to insert spectacle lenses 2 and/or clamping rings 17 with spectacle lenses 2 held therein into a carrier 20, in particular in an automated manner.

Preferably, the fourth handling device 9J comprises a gripper or suction cup or the like for removing clamping rings 17 with spectacle lenses 2 held therein from the transport device 19C and/or for inserting them into the carrier 20.

Preferably, the coating installation 4 and/or the handling system 4B and/or the second coating apparatus 9 has a handling device 9K, hereinafter referred to in particular as the fifth handling device 9K.

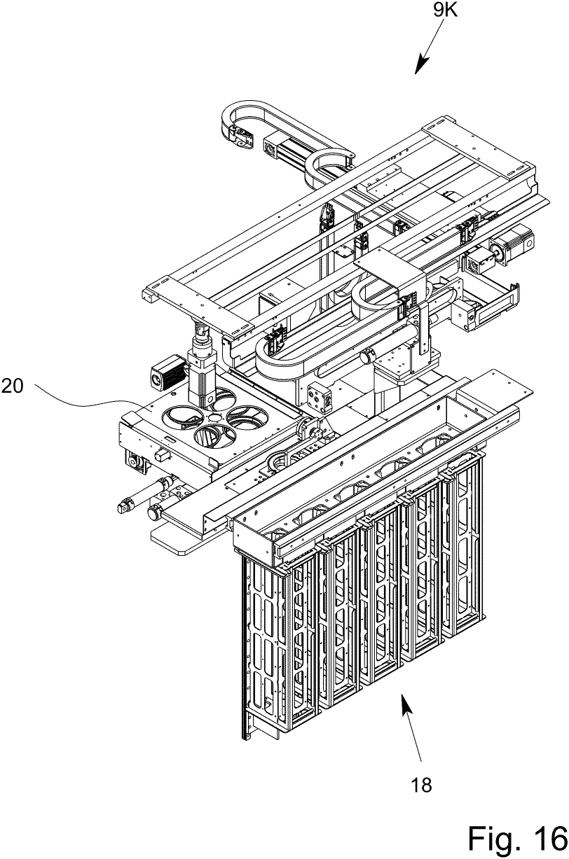

The fifth handling device 9K is in particular shown in FIG. 16.

Preferably, the fifth handling device 9K is arranged downstream of the coating chambers 9A and/or the outlet chamber 9F.

The fifth handling device 9K is preferably adapted to remove spectacle lenses 2 and/or clamping rings 17, in particular in an automated manner, with spectacle lenses 2 held therein from a carrier 20.

The second coating apparatus 9 preferably has a removal device 23 for removing the spectacle lenses 2 from the clamping rings 17, in particular automatically. The removal device 23 is preferably identical in construction to the clamping device 21 described above. The removal device 23 is preferably arranged downstream of the coating chambers 9A and/or the outlet chamber 9F.

The second coating apparatus 9 preferably comprises a magazine 18 for the clamping rings 17, which is preferably arranged downstream of the outlet chamber. The magazine 18 of the second coating apparatus 9 is preferably of identical construction to the magazine 18 of the intermediate storage apparatus 8. Preferably, the magazine units 18A with clamping rings 17 arranged therein are removable from the magazine 18 so that the clamping rings 17 can be cleaned.

The fifth handling device 9K is preferably adapted to remove clamping rings 17 with spectacle lenses 2 held therein from the carrier 20 and/or insert them into the removal device 23.

The return transport device 9D preferably connects the fifth handling device 9K to the fourth handling device 9J, so that the carriers 20 can be transported (back) from the fifth handling device 9K to the fourth handling device 9J, in particular in an automated manner.

Furthermore, the fifth handling device 9K is preferably configured to remove spectacle lenses 2, in particular in an automated manner, from the removal device 23 and/or the clamping rings 17 and/or to deposit them in transport containers 11D.

During the processing and/or coating of the spectacle lenses 2 in the coating installation 4, the order of the spectacle lenses 2 is preferably maintained. In particular, thus, after passing through the coating installation 4, the spectacle lenses 2 are deposited back into the transport containers 11D in the same order in which they were removed from the transport containers 11D and/or transferred / handed over to the coating installation 4 before being coated in the coating installation 4. This is achieved in particular by the serial and/or linear arrangement of the apparatuses 6 to 9 of the coating installation 4. This ensures that, after passing through the coating installation 4, the spectacle lenses 2 are deposited again in the same transport containers 11D from which they were previously removed.

For this purpose, the transport containers 11D are preferably transported past the coating installation 4 and/or transported from the transfer device 6P at the beginning of the coating installation 4 to the fifth handling device 9K at the end of the coating installation 4, while the spectacle lenses 2 are coated in the coating installation 4 and/or pass through the coating installation 4.

Furthermore, the fifth handling device 9K is preferably adapted to remove clamping rings 17, in particular in an automated manner, from the removal device 23 and/or to insert them into the magazine 18.

The carriers 20 are preferably removable from the second coating apparatus 9 and/or transport device 9C, so that they can be cleaned and, after cleaning, reinserted into the second coating apparatus 9 and/or transport device 9C.

Preferably, the second coating apparatus 9 is designed in such a way that a spectacle lens 2 passing through the coating apparatus 9 is coated, in particular only on one flat side 2A, 2B. In particular, the second coating apparatus 9 is designed in such a way that no coating of the flat side 2A, 2B which is not to be coated takes place and/or no coating material is deposited on the flat side 2A, 2B which is not to be coated.

According to a further aspect, which is also independently realizable or may form an independent invention, a coating installation 4 is proposed comprising two or more (second) coating apparatuses 9. In various combinations, the features of the coating installation 4 and/or second coating apparatus 9 explained above may form further (optional) features of the coating installation 4 comprising two or more second coating apparatuses 9.

Preferably, the coating installation 4 comprises two or more second coating apparatuses 9, each comprising a plurality of coating chambers 9A. The two or more second coating apparatuses 9 may be identical or different in design, for example differing in the number, type, sequence and/or configuration of the coating chambers 9A.

In particular, the second coating apparatuses 9 are each designed as previously described.

The coating chambers 9A of the second coating apparatuses 9 are preferably each arranged in series, in particular linearly one behind the other, and/or form a continuous vacuum system as described above. Alternatively or additionally, the second coating apparatuses 9 may also each have coating chambers 9A arranged in parallel. Thus, any combinations of parallel and/or serially arranged coating chambers 9A in the second coating apparatuses 9 are possible.

Preferably, the second coating apparatuses 9 are arranged in or enclosed by a common housing or casing, and/or the second coating apparatuses 9 comprise a common housing or casing.

The two or more second coating apparatuses 9 are preferably arranged and/or operable in parallel. In particular, the spectacle lenses 2 in the coating installation 4 are selectively conveyable to or transferable to one of the second coating apparatuses 9, and/or the coating installation 4 and/or the handling system 4B is designed for this purpose. Alternatively or additionally, the spectacle lenses 2 may be conveyable to the second coating apparatuses 9 a plurality of times and/or may be conveyable to different ones of the second coating apparatuses 9 in succession. In particular, the second coating apparatuses 9 may form a plurality of and/or different circuits and/or ring systems.

Alternatively or in addition to the design of the coating installation 4 with two second coating apparatuses 9, two or more coating installations 4 may also be arranged and/or operated in parallel. In particular, the processing installation 1 can have two or more coating installations 4 which are arranged and/or operated in particular parallel to one another. The coating installations 4 are preferably each designed as described above. The two or more coating installations 4 may be of identical or different design. In a processing installation 1 with two or more coating installations 4, the spectacle lenses 2 can preferably be selectively fed to one of the two or more coating installations 4 and/or transferred thereto.

### Procedural Aspects

According to a further aspect which can also be implemented independently, the present invention relates to a method for applying a permanent coating 5 to the first and the second flat side 2A, 2B of a spectacle lens 2. Preferably, for this purpose the coating installation 4 is run through twice and/or the spectacle lens 2 is coated twice in the coating installation 4.

Preferably, therefore, after one of the flat sides 2A, 2B has been coated or provided with the permanent coating 5 in the coating installation 4, the spectacle lens 2 is transported back and then the flat side 2A, 2B which has not yet been coated is coated or provided with the coating 5.

Preferably - in particular after the coating 5 has been applied to a flat side 2A, 2B in the coating installation 4 and preferably before the spectacle lens 2 is transported back - the removable cover layer 12B applied before the application of the permanent coating 5 is removed from the spectacle lens 2, in particular in an automated manner. This is preferably done in the removal apparatus 15, but can in principle also be done in the second coating apparatus 9, the deblocking apparatus 3G and/or the cover layer apparatus 3H.

Before applying a permanent coating 5 to the flat side 2A, 2B not yet coated and/or before the second pass through the coating installation 4, a removable cover layer 12B is preferably applied to the flat side 2A, 2B provided with a permanent coating 5 during the first pass through the coating installation 4, in particular in the cover layer apparatus 3H.

Subsequently, the spectacle lens 2 is transported to the coating installation 4, where a permanent coating 5 is also applied to the flat side 2A, 2B which has not yet been coated.

For the return transport of spectacle lenses 2, the processing installation 1 and/or the transport system 11 and/or the coating installation 4 preferably comprises a return transport apparatus 16. The return transport apparatus 16 preferably runs - at least in sections or predominantly - parallel to the first, second and/or third transport track T1, T2, T3 and/or parallel to and/or along the coating installation 4. Preferably, the return transport apparatus 16 comprises a transport track or the return conveyor device 16 is formed by a transport track. Preferably, the return transport apparatus 16 is arranged outside the casing 4A of the coating installation 4.

Preferably, the return transport apparatus 16 connects the detaching apparatus 15 or the coating installation 4 to the deblocking apparatus 3G and/or cover layer apparatus 3H and/or the return transport apparatus 16 is designed for transporting spectacle lenses 2 past the coating installation 4 and/or from the coating installation 4 or detaching apparatus 15 to the deblocking apparatus 3G and/or cover layer apparatus 3H. In principle, however, the return transport apparatus 16 can alternatively or additionally also connect the detaching apparatus 15 or coating installation 4 to another device or processing apparatus 3 of the processing installation 1 and/or transport track T1, T2, T3 of the transport system 11.

According to another aspect, which may also be implemented independently, the clamping rings 17 and/or carriers 20 are regularly cleaned. During the application of the coating 5 and/or layers 5B in the second coating apparatus 9, some of the coating material may also settle on the clamping rings 17 and/or carriers 20. In order to prevent coating material which has settled one the clamping rings 17 and/or carriers 20 during a previous coating operation from entering the coating chambers 9A and/or onto the spectacle lenses 2 when the clamping rings 17 and/or carriers 20 are used again, the clamping rings 17 and/or carriers are preferably cleaned after one or more uses, in particular regularly and/or at predetermined intervals. This is conducive to a high and consistent quality of the spectacle lenses 2 and/or coating 5.

The clamping rings 17 are preferably cleaned after each use. The carriers 20 are preferably cleaned after more than five and/or less than fifteen, in particular after about 10, uses. A use is understood here as a use of a clamping ring 17 and/or carrier 20 for holding one or more spectacle lenses 2 during the application of the coating in the second coating apparatus 9.

For cleaning the clamping rings 17 and/or carriers 20, the processing installation 1 and/or coating installation 4 may comprise one or more cleaning apparatuses. In particular, separate cleaning apparatuses may be provided for the clamping rings 17 and the carriers 20. Preferably, the cleaning and/or the transport of the clamping rings 17 and/or carriers 20 to and from the corresponding cleaning apparatuses is fully automated.

According to a further aspect which can also be implemented independently, the present invention relates to a method of manufacturing spectacle lenses 2 in which a flat side 2A, 2B of the spectacle lenses 2 is formed into a desired prescription surface by shaping processing and subsequently a permanent coating 5 is applied at least to the flat side 2A, 2B formed into the prescription surface.

In order to form the prescription surface, parallel processing of the spectacle lenses 2 takes place, in which different spectacle lenses 2 are processed simultaneously in separate processing apparatuses 3, with the same type of processing taking place in at least two of the processing apparatuses 3.

The permanent coating 5 is applied to the spectacle lenses 2 in a coating installation 4 having serially arranged devices 6-9 for performing various steps of applying the coating 5, each of the spectacle lenses 2 passing through each of the devices 6-9 of the coating installation 4.

In this method, the spectacle lenses 2 are transported in a fully automated manner to the processing apparatuses 3 and from the processing apparatuses 3 to the coating installation 4 and transferred to the coating installation 4.

As mentioned above, during the processing and/or coating of the spectacle lenses 2 in the coating installation 4, the order of the spectacle lenses 2 is preferably maintained and/or, after passing through the coating installation 4, the spectacle lenses 2 are preferably each deposited again in the same transport container 11D from which they were previously removed. To ensure or guarantee this, the processing installation 1 and/or coating installation 4 preferably comprises a control center and/or a control device 4C.

The control center and/or control device 4C is preferably configured to track and/or record the position of the lenses 2 in the coating installation 4 and/or to ensure that the lenses 2 are returned to the same transport container 11D from which they were previously removed after passing through the coating installation 4.

This can be done, for example, by recording or tracking from which transport container 11D a spectacle lens 2 is removed. For this purpose, the transport container preferably has an identification means, such as a barcode or the like, which is read by a reader of the control center and/or the control device 4C. Furthermore, the spectacle lens 2 may also have an identification means such as a marking or the like. However, it is also possible that an identification means such as a code, an identification number or the like is assigned internally in the control center and/or the control device 4C to each spectacle lens 2 which is fed to the coating installation 4 and that further information is stored for this identification means, for example when the spectacle lens 2 is transferred between the devices 6 to 9 and/or is processed in one of the devices 6 to 9.

Before the spectacle lens 2 is deposited again in the transport container 11D after passing through the coating installation 4, the control device 4C and/or the control center preferably checks or ensures that the transport container 11D is the one from which the spectacle lens 2 was previously removed. This is done in particular by (re)reading the identification means of the transport container 11D and comparing or checking, on the basis of the identification means of the spectacle lens 2, whether the spectacle lens was previously removed from this transport container 11D.

By means of the control center and/or the control device 4C, a correct allocation of the spectacle lenses 2 to the transport containers 11D can be ensured, in particular in the event of malfunctions, failures and/or errors.

Individual features and aspects of the present invention may be implemented independently, but also in various combinations.

Aspects of the present invention which are realizable independently of each other, but also in various combinations with the aspects and features explained above, are in particular:

1. Coating installation 4 comprising at least one coating apparatus 7, 9 for applying a permanent coating 5 to a spectacle lens 2,

characterized
in that the coating installation 4 has a handling system 4B for the automated handling of holders, in particular clamping rings 17, for temporarily holding the spectacle lens 2 during the application of the coating 5, and/or
in that the coating installation 4 comprises a first coating apparatus 7 for applying a first layer/hard layer 5A to the spectacle lens 2, a second coating apparatus 9 for applying a second layer/functional layer 5B to the spectacle lens 2 or the first layer, and an intermediate storage apparatus 8 for the intermediate storage of spectacle lenses 2 after the application of the first layer/hard layer 5A and/or before the application of the second layer/functional layer 5B, wherein the coating installation 4 comprises a handling system 4B for the automatic transfer of spectacle lenses 2 between the first and/or second coating apparatus 7, 9 and the intermediate storage apparatus 8, and/or
in that the coating installation 4 is designed for the fully automated coating of spectacle lenses 2 successively in two different coating apparatuses 7, 9.

2. Coating installation according to aspect 1, characterized in that the handling system 4B and/or the intermediate storage apparatus 8 comprises a handling device 8A having one or more suction cups or grippers for holding and/or handling a holder/clamping ring 17 preferably designed according to one of aspects 14 to 23, preferably wherein the handling device 8A comprises or is formed by a robot.

3. Coating installation according to aspect 2, characterized in that the handling device 8A is configured for the of handling spectacle lenses 2 in addition to the handling of holders/clamping rings 17.

4. Coating installation according to one of the preceding aspects, characterized in that the coating installation 4 and/or intermediate storage apparatus 8 has a magazine 18, preferably designed according to one of aspects 24 to 26, for storing holders/clamping rings 17 for the spectacle lenses 2.

5. Coating installation according to aspect 4, characterized in that the magazine 18 comprises a magazine unit 18A, the magazine unit 18A being removable from the magazine 18 together with holders/clamping rings 17 arranged therein.

6. Coating installation according to one of the preceding aspects, characterized in that the coating installation 4 and/or intermediate storage apparatus 8 comprises a clamping device 21 for automated opening and/or closing of a clamping ring 17 and/or for automated insertion of a spectacle lens 2 into a clamping ring 17.

7. Coating installation according to one of the preceding aspects, characterized in that the coating installation 4 and/or intermediate storage apparatus 8 has a heating device 19 for heating spectacle lenses 2, preferably held in holders/clamping rings 17, so that a hard coating 5A previously applied to the spectacle lenses 2 dries and/or cures in the heating device 19.

8. Coating installation according to aspect 7, characterized in that the coating installation 4 and/or heating device 19 comprises a transport device 19C for the continuous transport of spectacle lenses 2, preferably held in holders/clamping rings 17, through the heating device 19, wherein the heating device 19 is designed for heating the spectacle lenses 2 during transport with the transport device 19C.

9. Coating installation according to of the preceding aspects, characterized in that the coating installation 4 and/or handling system 4B comprises a handling device 9K for transferring spectacle lenses 2 and/or clamping rings 17 with spectacle lenses 2 held therein from the intermediate storage apparatus 8 and/or heating device 19 to the second coating apparatus 9.

10. Coating installation according to one of the preceding aspects, characterized in that the coating installation 4 and/or second coating apparatus 9 comprises at least one carrier 20 for receiving a plurality of spectacle lenses 2 held in holders/clamping rings 17.

11. Coating installation according to aspect 10, characterized in that the carrier 20 is configured as a cover for a coating chamber 9A of the second coating apparatus 9 and/or is configured to close a coating chamber 9A of the second coating apparatus 9 during a coating process, in particular in a gas-tight and/or vacuum-tight manner.

12. Coating installation according to aspect 10 or 11, characterized in that the coating installation 4 and/or second coating apparatus 9 is configured for automated return transport of the carrier 20 after passing through the second coating apparatus 9.

13. Coating installation according to one of the preceding aspects, characterized in that the clamping rings 17 are designed according to one of aspects 14 to 23.

14. Clamping ring 17 with several flexible, in particular elastic, arms 17A for clamping a spectacle lens 2 at the edge,

characterized
in that the clamping ring 17 comprises an orientation means 17E for oriented gripping or handling of the clamping ring 17 and/or for oriented insertion of the clamping ring 17 into a magazine 18 and/or a carrier 20, and/or
in that the clamping ring 17 has a suction surface 17F for handling the clamping ring 17 by means of a suction cup, and/or
in that the clamping ring 17 is designed in such a way that a plurality of identical clamping rings 17 can be stacked vertically in such a way that arms 17A of adjacent clamping rings 17 are spaced apart.

15. Clamping ring according to aspect 14, characterized in that the orientation means 17E is arranged on an outer surface of the clamping ring 17 and/or comprises or is formed by one or more recesses, preferably wherein the recesses are arranged asymmetrically on the clamping ring 17.

16. Clamping ring according to aspect 14 or 15, characterized in that the orientation means (17E) is arranged on an outer side of the clamping ring (17).

17. Clamping ring according to one of aspects 14 to 16, characterized in that the suction surface (17F) is formed by a flange (17D) and/or is ring-shaped.

18. Clamping ring according to one of aspects 14 to 17, characterized in that the arms (17A) are leaf springs.

19. Clamping ring according to one of aspects 14 to 18, characterized in that the arms (17A) are curved, in particular at least substantially semicircular in shape.

20. Clamping ring according to one of aspects 14 to 19, characterized in that the clamping ring (17) comprises a ring-like frame (17B), the arms (17A) being attached at one end to the frame (17B) and projecting inwardly from the frame (17B).

21. Clamping ring according to one of aspects 14 to 20, characterized in that the suction surface 17F is formed by a flange 17D and/or is ring-shaped and/or extends or is arranged at least substantially parallel to a plane in which the spectacle lens 2 is clamped or can be clamped.

22. Clamping ring according to one of aspects 14 to 21, characterized in that the clamping ring 17 comprises a frame 17B to which the arms 17A are attached, the frame 17B projecting radially inwardly and/or perpendicularly to a plane in which the spectacle lens 2 is clamped or clampable above the arms 17A.

23. Clamping ring according to one of aspects 14 to 22, characterized in that the clamping ring 17 and/or frame 17B comprises, in particular on a bottom side, at least one recess 17G.

24. Magazine 18 for storing several clamping rings 17 for spectacle lenses 2,

characterized
in that the magazine 18 has at least one magazine unit 18A which can be removed from the magazine 18 together with clamping rings 17 arranged in the magazine unit 18A, and/or
in that the clamping rings 17 have an orientation means 17E and the magazine 18 and/or the magazine unit 18A has an orientation means 18B corresponding to the orientation means 17E of the clamping rings 17, so that the clamping rings 17 can only be stored in a predetermined orientation or rotational position in the magazine 18, and/or
in that the clamping rings 17 are designed according to one of aspects 14 to 23.

25. Magazine according to aspect 24, characterized in that in the magazine 18 and/or the magazine unit 18A a plurality of clamping rings 17 can be stored stacked on top of each other in the same orientation or rotational position.

26. Magazine according to aspect 24 or 25, characterized in that the magazine 18 and/or the magazine unit 18A is columnar.

27. Processing installation 1 for processing spectacle lenses 2,
with several separate and independently operating processing apparatuses 3,
   wherein at least one of the processing apparatuses 3 is designed for shaping processing/machining of spectacle lenses 2 and preferably at least one of the processing apparatuses 3 is designed for polishing spectacle lenses 2,
   wherein the processing installation 1 is designed for the simultaneous processing of spectacle lenses 2 in different processing apparatuses 3,
with several transport tracks T1, T2, T3, so that spectacle lenses 2 can be conveyed past processing apparatuses 3 and/or can be circulated,
with a coating installation 4 directly adjoining the processing apparatuses 3 and connected to one of the transport tracks T1, T2, T3, and a transfer device 6P for the automated transfer of the spectacle lenses 2 from the transport track T1, T2, T3 to the coating installation 4,
   wherein the coating installation 4 comprises a plurality of coating chambers 9A for applying different layers 5B to the spectacle lenses 2,
   wherein the coating chambers 9A form a continuous vacuum system, and
   wherein the coating chambers 9A are arranged in series and are directly connected to each other so that the lenses 2 pass through each of the coating chambers 9A.

28. Processing installation according to aspect 27, characterized in that the coating installation 4 is designed according to one of aspects 1 to 13 and/or comprises at least one clamping ring 17 according to one of aspects 14 to 23 and/or comprises a magazine 18 according to one of aspects 24 to 27.

29. Method for applying a permanent coating 5 to spectacle lenses 2 in a coating installation 4, preferably wherein the coating installation 4 is designed according to one of aspects 1 to 13,
wherein the spectacle lenses 2 are temporarily held in clamping rings 17, preferably designed according to one of aspects 14 to 18, during the application of the permanent coating 5, and wherein the coating installation 4 opens and/or closes the clamping rings 17 in an automated manner and/or inserts spectacle lenses 2 into the clamping rings 17 and/or removes them from the clamping rings 17 in an automated manner, and/or
wherein the spectacle lenses 2 and/or clamping rings 17 are automatically inserted indirectly or directly into carriers 20, which in particular rotatably hold the spectacle lenses 2 and/or clamping rings 17 during the application of the coating 5 and/or cover individual coating chambers 9A during the application of the coating 5, and/or are automatically removed therefrom.

30. Method according to aspect 29, characterized in that the clamping rings 17 are held in a defined orientation or rotational position for opening and/or closing and/or inserting and/or removing a spectacle lens 2.

31. Method for applying a permanent coating 5 to a first and a second flat side 2A, 2B of a spectacle lens 2,
wherein a removable cover layer 12B is applied to the first flat side 2A of the spectacle lens 2 in a cover layer apparatus 3H, and thereafter a permanent coating 5 is applied to the second flat side 2B,
wherein after the application of the permanent coating 5 to the second flat side 2B, the removable cover layer 12B is removed from the spectacle lens 2 in an automated manner and the spectacle lens 2 is transported back to the cover layer apparatus 3H in an automated manner, and
wherein in the cover layer apparatus 3H, a removable cover layer 12B is applied to the second flat side 2B, and thereafter a permanent coating 5 is applied to the first flat side 2A.

32. Method for processing a spectacle lens 2,
wherein the spectacle lens 2 is machined and preferably polished in one or more processing apparatuses 3,
wherein a first flat side 2A of the spectacle lens 2 is provided with a removable protective layer 12A before the shaping processing/machining, and preferably the spectacle lens 2 is blocked at the first flat side 2A,
wherein the protective layer 12A is removed after the shaping processing/machining of the second flat side 2B and in particular after blocking, and after removal of the protective layer 12A the first flat side 2A of the spectacle lens 2 is provided with a removable cover layer 12B, and
wherein a permanent coating 5 is subsequently applied to the second flat side 2B of the spectacle lens 2.

33. Method for applying a permanent coating 5 to spectacle lenses 2 in a coating installation 4,
wherein the spectacle lenses 2 are coated simultaneously in batch sizes of at most eight spectacle lenses 2 and/or at least two different layers 5A, 5B of the coating 5 are applied in a fully automated manner in the coating installation 4,
wherein the spectacle lenses 2 are transported in transport containers 11D to the coating installation 4 and are removed from the transport containers 11D for coating and transferred to the coating installation 4, and
wherein the transport containers 11D are transported past the coating installation 4 during the application of the coating 5, and the spectacle lenses 2 are each deposited again in the same transport container 11D from which they were previously removed after the application of the coating 5.

34. Method for manufacturing spectacle lenses 2,
wherein a flat side 2A, 2B of the spectacle lenses 2 is formed into a desired prescription surface by shaping processing/machining, and subsequently a permanent coating 5 is applied at least to the flat side 2A, 2B formed into the prescription surface,
wherein, in order to form the prescription surface, parallel processing of the spectacle lenses 2 takes place, in which different spectacle lenses 2 are processed simultaneously in separate processing apparatuses 3, the same type of processing taking place in at least two of the processing apparatuses 3,
wherein the permanent coating 5 is applied to the spectacle lenses 2 in a coating installation 4 comprising serially arranged apparatuses 6-9 for carrying out different steps of applying the coating 5, each of the spectacle lenses 2 passing through each of the devices 6-9 of the coating installation 4, and
wherein the spectacle lenses 2 are transported in a fully automated manner to the processing apparatuses 3 and from the processing apparatuses 3 to the coating installation 4 and transferred to the coating installation 4.

List of Reference signs:

| | |
|---|---|
| 1 | Processing installation |
| 2 | Spectacle Lens |
| 2A | First flat side |
| 2B | Second flat side |
| 2C | Edge |
| 3 | Processing apparatus |
| 3A | Machining apparatus |
| 3B | Polishing apparatus |
| 3C | Protective layer apparatus |
| 3D | Blocking apparatus |
| 3E | Storage apparatus |
| 3F | Marking apparatus |
| 3G | Deblocking apparatus |
| 3H | Cover layer apparatus |
| 4 | Coating installation |
| 4A | Casing |
| 4B | Handling system |
| 4C | Control device |
| 5 | Coating |
| 5A | Hard layer |
| 5B | Functional layer |
| 6 | Cleaning apparatus |
| 6A | First cleaning chamber |
| 6B | Second cleaning chamber |
| 6C | Brush |
| 6D | Applicator |
| 6E | Drying device |
| 9B | Cathode |
| 9C | Transport device of 9 |
| 9D | Return transport device of 9 |
| 9E | Inlet chamber |
| 9F | Outlet chamber |
| 9G | Closure |
| 9H | (Additional) Closure |
| 9J | (Fourth) Handling device |
| 9K | (Fifth) Handling device |
| 10 | Edge processing apparatus |
| 11 | Transport system |
| 11A | Conveying device |
| 11B | Changeover device |
| 11C | Conveying device |
| 11D | Transport container |
| 12A | Protective layer |
| 12B | Cover layer |
| 13 | Block piece |
| 14 | Blocking material |
| 15 | Detaching apparatus |
| 16 | Return transport apparatus |
| 17 | Clamping ring |
| 17A | Arm |
| 17B | Frame |
| 17C | Portion |
| 17D | Flange |
| 17E | Orientation means |
| 17F | Suction surface |
| 17G | Recess |
| 17H | Bottom side |
| 18 | Magazine |
| 18A | Magazine unit |
| 18B | Orientation means |
| 19 | Heating device |
| 19A | Inlet |
| 19B | Outlet |
| 19C | Transport device |
| 19D | Strip |
| 19E | Storage location |
| 19F | Receptacle of 19E |
| 19G | Engagement element of 19E |
| 20 | Carrier |
| 20 | Receptacle of 20 |
| 21 | Clamping device |
| 21A | Receptacle of 21 |
| 21B | Opening device |
| 21C | Pin |
| 21D | Fixing means |
| 21E | Engagement element |
| 22 | Measuring device |
| 23 | Removal device |
| D | Axis of rotation |
| P | Arrow |
| P1 | First pair of grippers 7B |
| P2 | Second pair of grippers 7B |
| R1 | Transport direction of T1 |
| R2 | Transport direction of T2 |
| R3 | Transport direction of T3 |
| R4 | Transport direction of 19C |
| T1 | First transport track |
| T2 | Second transport track |
| T3 | Third transport track |

1. Coating installation (4) with at least one coating apparatus (7, 9) for applying a permanent coating (5) to a spectacle lens (2),
characterized
in that the coating installation (4) comprises a first coating apparatus (7) for applying a first layer / hard layer (5A) to the spectacle lens (2), a second coating apparatus (9) for applying a second layer / functional layer (5B) to the spectacle lens (2) or the first layer, and an intermediate storage apparatus (8) for the intermediate storage of spectacle lenses (2) after the application of the first layer or hard layer (5A) and/or before the application of the second layer / functional layer (5B), wherein the coating installation (4) comprises a handling system (4B) for the automatic transfer of spectacle lenses (2) between the first and/or second coating apparatus (7, 9) and the intermediate storage apparatus (8), and/or
in that the coating installation (4) is designed for the fully automated coating of spectacle lenses (2) successively in two different coating apparatuses (7, 9), and/or
in that the coating installation (4) has a handling system (4B) for the automated handling of holders, in particular clamping rings (17), for temporarily holding the spectacle lens (2) during the application of the coating (5).

2. Coating installation according to claim 1, characterized in that the handling system (4B) and/or the intermediate storage apparatus (8) comprises a handling device (8A) with one or more suction cups or grippers for holding and/or handling a holder/clamping ring (17), preferably designed according to one of claims 15 to 24.

3. Coating installation according to claim 2, characterized in that the handling device (8A) comprises or is formed by a robot.

4. Coating installation according to claim 2 or 3, characterized in that the handling device (8A) is designed for the handling of spectacle lenses (2) in addition to the handling of holders/clamping rings (17).

5. Coating installation according to one of the preceding claims, characterized in that the coating installation (4) and/or intermediate storage apparatus (8) has a magazine (18), preferably designed according to one of claims 25 to 27, for storing holders/clamping rings (17) for the spectacle lenses (2).

6. Coating installation according to claim 5, characterized in that the magazine (18) comprises a magazine unit (18A), the magazine unit (18A) being removable from the magazine (18) together with holders/clamping rings (17) arranged therein.

7. Coating installation according to one of the preceding claims, characterized in that the coating installation (4) and/or intermediate storage apparatus (8) has a clamping device (21) for the automated opening and/or closing of a holder/clamping ring (17) and/or for the automated insertion of a spectacle lens (2) into a holder/clamping ring (17).

8. Coating installation according to one of the preceding claims, characterized in that the coating installation (4) and/or intermediate storage apparatus (8) has a heating device (19) for heating spectacle lenses (2), preferably held in holders/clamping rings (17), so that a hard coating (5A) previously applied to the spectacle lenses (2) dries and/or cures in the heating device (19).

9. Coating installation according to claim 8, characterized in that the coating installation (4) and/or heating device (19) has a transport device (19C) for the continuous transport of spectacle lenses (2), preferably held in holders/clamping rings (17), through the heating device (19), the heating device (19) being designed for heating the spectacle lenses (2) during transport by the transport device (19C).

10. Coating installation according to one of the preceding claims, characterized in that the coating installation (4) and/or handling system (4B) comprises a handling device (9K) for transferring spectacle lenses (2) or holders/clamping rings (17) with spectacle lenses (2) held therein from the intermediate storage apparatus (8) or heating device (19) to the second coating apparatus (9).

11. Coating installation according to one of the preceding claims, characterized in that the coating installation (4) and/or second coating apparatus (9) comprises at least one carrier (20) for receiving a plurality of spectacle lenses (2) held in holders/clamping rings (17).

12. Coating installation according to claim 11, characterized in that the carrier (20) is designed as a cover for a coating chamber (9A) of the second coating apparatus (9) and/or is designed to close a coating chamber (9A) of the second coating apparatus (9) during a coating process, in particular in a gas-tight and/or vacuum-tight manner.

13. Coating installation according to claim 11 or 12, characterized in that the coating installation (4) and/or second coating apparatus (9) is designed for automated return transport of the carrier (20) after passing through the second coating apparatus (9).

14. Coating installation according to one of the preceding claims, characterized in that the clamping rings (17) are designed according to one of claims 15 to 24.

15. Clamping ring (17) with several flexible, in particular elastic, arms (17A) for clamping a spectacle lens (2) at the edge,
characterized
in that the clamping ring (17) comprises an orientation means (17E) for oriented gripping or handling of the clamping ring (17) and/or for oriented insertion of the clamping ring (17) into a magazine (18) and/or a carrier (20), wherein the orientation means (17E) comprises or is formed by one or more recesses, and/or
in that the clamping ring (17) is designed in such a way that a plurality of identical clamping rings (17) can be stacked vertically in such a way that the arms (17A) of adjacent clamping rings (17) are spaced apart, and/or
in that the clamping ring (17) has a suction surface (17F) for handling the clamping ring (17) by means of a suction cup.

16. Clamping ring according to claim 15, characterized in that the recesses are arranged asymmetrically on the clamping ring (17).

17. Clamping ring according to claim 15 or 16, characterized in that the orientation means (17E) is arranged on an outer side of the clamping ring (17).

18. Clamping ring according to one of claims 15 to 17, characterized in that the suction surface (17F) is formed by a flange (17D) and/or is ring-shaped.

19. Clamping ring according to one of claims 15 to 18, characterized in that the arms (17A) are leaf springs.

20. Clamping ring according to one of claims 15 to 19, characterized in that the arms (17A) are curved, in particular at least substantially semicircular in shape.

21. Clamping ring according to one of claims 15 to 20, characterized in that the clamping ring (17) comprises a ring-like frame (17B), the arms (17A) being attached at one end to the frame (17B) and projecting inwardly from the frame (17B).

22. Clamping ring according to one of claims 15 to 21, characterized in that the suction surface (17F) extends and/or is arranged at least substantially parallel to a plane in which the spectacle lens (2) is clamped or clampable.

23. Clamping ring according to one of claims 15 to 22, characterized in that the clamping ring (17) comprises a frame (17B) to which the arms (17A) are attached, the frame (17B) projecting radially inwardly and/or perpendicularly to a plane in which the lens (2) is clamped or clampable above the arms (17A).

24. Clamping ring according to one of claims 15 to 23, characterized in that the clamping ring (17) and/or frame (17B) comprises, in particular on a bottom side, at least one recess (17G).

25. Magazine (18) for storing several clamping rings (17) for spectacle lenses (2),
characterized
in that the magazine (18) has at least one magazine unit (18A) which can be removed from the magazine (18) together with clamping rings (17) arranged in the magazine unit (18A), and/or
in that the clamping rings (17) have an orientation means (17E) and the magazine (18) and/or the magazine unit (18A) has an orientation means (18B) corresponding to the orientation means (17E) of the clamping rings (17), so that the clamping rings (17) can be stored in the magazine (18) only in a predetermined orientation or rotational position, and/or
in that the clamping rings (17) are designed according to one of claims 15 to 24.

26. Magazine according to claim 21, characterized in that in the magazine (18) and/or the magazine unit (18A) several clamping rings (17) can be stored stacked on top of each other in the same orientation or rotational position.

27. Magazine according to claim 21 or 22, characterized in that the magazine (18) and/or the magazine unit (18A) is columnar.

28. Method of applying a permanent coating (5) to spectacle lenses (2) in a coating installation (4), preferably wherein the coating installation (4) is designed according to one of claims 1 to 14,
wherein the spectacle lenses (2) are temporarily held in clamping rings (17), preferably designed according to one of claims 15 to 24, during the application of the permanent coating (5), and wherein the coating installation (4) opens and/or closes the clamping rings (17) in an automated manner and/or inserts spectacle lenses (2) into the clamping rings (17) and/or removes them from the clamping rings (17) in an automated manner, and/or
wherein the spectacle lenses (2) and/or clamping rings (17) are automatically inserted indirectly or directly into carriers (20), which in particular rotatably hold the spectacle lenses (2) or clamping rings (17) during the application of the coating (5) and/or cover individual coating chambers (9A) during the application of the coating (5), and/or are automatically removed therefrom.

29. Method according to claim 28, characterized in that the clamping rings (17) are held in a defined orientation or rotational position for opening and/or closing and/or inserting and/or removing a spectacle lens (2).
